(19) United States
(12) Patent Application Publication
(10) Pub. No.: US 2019/0277894 A1
(43) Pub. Date: Sep. 12, 2019

(54) WAVEFORM DISAGGREGATION APPARATUS, METHOD AND NON-TRANSITORY MEDIUM

(71) Applicant: NEC Corporation, Minato-ku, Tokyo (JP)

(72) Inventors: Ryota SUZUKI, Tokyo (JP); Shigeru KOUMOTO, Tokyo (JP); Murtuza PETLADWALA, Tokyo (JP)

(73) Assignee: NEC Corporation, Minato-ku, Tokyo (JP)

(21) Appl. No.: 16/331,193

(22) PCT Filed: Sep. 11, 2017
(86) PCT No.: PCT/JP2017/032704

§ 371 Date: Mar. 7, 2019

(30) Foreign Application Priority Data
Sep. 12, 2016 (JP) 2016-177605
May 19, 2017 (JP) 2017-100130

(51) Int. Cl. G01R 21/133

(52) U.S. Cl. CPC G01R 21/133

(57) ABSTRACT

A waveform disaggregation apparatus includes a storage apparatus that stores, as a model of an operation state of a unit, a first state transition model including a segment in which each state transition occurs along a one directional single path; and an estimation section that receives a composite signal waveform of a plurality of units including a first unit that operates based on the first state transition model and that at least based on the first state transition model, performs estimation of a signal waveform of the first unit from the composite signal waveform to separate the signal waveform therefrom.

### CROSS-REFERENCE TO RELATED APPLICATIONS

The present application claims priority from Japanese Patent Application No. 2016-177605 (filed on Sep. 12, 2016) and Japanese Patent Application No. 2017-100130 (filed on May 19, 2017), the contents of which are hereby incorporated in their entirety by reference into this specification. The present invention relates to a waveform disaggregation apparatus, a method and a program.

### BACKGROUND

There have been various proposals for technology for non-intrusively estimating the state of an electrical device based on electrical current measured from a switchboard (distribution board) (Non-intrusive Load Monitoring: NILM, or Non-intrusive Appliance Load Monitoring: NIALM).

For example, Patent Literature 1 discloses an electrical device monitoring system that includes a data extraction means for extracting data related to a current and a phase of the current to a voltage for each of fundamental wave and harmonics, from measured data detected by a measuring sensor installed near a feeder entrance to a house of a customer, and a pattern recognition means for estimating operation state of an electrical device used by the house of the customer, based on data related to a current and a phase of the current to the voltage for each of fundamental wave and harmonics, obtained by the data extraction means.

As related technology that performs waveform disaggregation based on a probability model, Patent Literature 2 for example, obtains data representing a sum of electrical signals of 2 or more electrical devices including a first electrical device, and by processing the data by using a probability generating model, generates an estimated value of an operation state of the first electrical device to output the estimated value of electrical signals of the first electrical device. The probability generating model has factors that represent 3 or more states and that correspond to the first electrical device. The probability generating model is a Factorial Hidden Markov Model (FHMM). The Factorial HMM has a second factor corresponding to a second electrical device among the 2 or more electrical devices, and by processing the data using the Factorial HMM, generates a second estimated value of a second electrical signal of the second electrical device, calculates a first individual distribution of estimated value of an electrical signal of the first electrical device, uses the first individual distribution as a parameter of a factor corresponding to the first electrical device, calculates a second individual distribution of the second estimated value of the second electrical signals of the second electrical device, and uses the second individual distribution as a parameter of a factor corresponding to the second electrical device.

With a normal HMM (Hidden Markov Model), one state variable Sₜ corresponds to observed data Yₜ at time t, but in Factorial HMM there are multiple (M) state variables Sₜ, Sₜ⁽¹⁾, Sₜ⁽²⁾ to Sₜ^{(M)}, and one observation data item Yₜ is generated based on the multiple state variables Sₜ⁽¹⁾ to Sₜ^{(M)}. The state variables Sₜ⁽¹⁾ to Sₜ^{(M)} respectively correspond to electrical devices. State values of the state variables Sₜ⁽¹⁾ to Sₜ^{(M)} correspond to states (operation state, for example, ON, OFF) of the electrical devices. In HMM an EM (Expectation-Maximization) algorithm used for estimating a parameter(s) from output (observation data) is an algorithm that maximizes logarithmic likelihood of observation data by repeating E (Expectation) and M (Maximization) steps, and includes the following steps 1 to 3.

1. Set initial parameters.
2. Compute expected value of likelihood of model based on distribution of presently estimated latent variables (E Step).
3. Find parameters to maximize expected value of likelihood obtained in the E Step (M Step). The parameters obtained in the M Step are used to determine distribution of latent variables used in a subsequent E Step, and steps 2 and 3 are repeated until the expected value converges (no longer increases).

Patent Literature 3 discloses an electrical device estimation apparatus including a data acquisition means for acquiring time series data for total value of consumption current of plural electrical devices, and a parameter estimating means for finding model parameters with operation states of the plural electrical devices being modeled by a probability model, based on the acquired time series data. The probability model is a Factorial HMM. The data acquisition means converts a total value of acquired consumption current into non-negative data, and the parameter estimating means, in parameter estimation processing by the EM algorithm, finds a parameter W^{(m)} of observation probability as the model parameter, by maximizing a likelihood function which is a degree describing a total value pattern for the consumption current represented by the time series data, by the Factorial HMM, under a constraint condition that observation probability parameter W^{(m)} corresponding to a current waveform pattern of factor m of the Factorial HMM, is non-negative.

Here, a description is given of an outline of waveform disaggregation using Factorial HMM disclosed in Patent Literature 2. FIG. 19 is a diagram illustrating an example of the outline based on FIG. 3 of Patent Literature 2 (component elements and reference symbols thereof are changed from Patent Literature 2). In waveform disaggregation learning, with assumption that current waveform Yₜ as total data of respective times t is an addition value (total) of each current waveform W^{(m)} of current consumed by each electrical device m, current waveform W^{(m)} consumed by each electrical device m is found from current waveform Yₜ.

A state estimation section 212 performs state estimation that estimates operation state of each home electric appliance, using current waveform Yₜ from a data acquisition unit 211, and model parameter φ of an overall model which is the overall model of electric appliances in a household stored in a model storage section 213.

The model learning section 214 performs model learning to update the model parameter φ of the overall model stored in a model storage unit 213, using the current waveform Yₜ supplied from the data acquisition unit 211 and the estimation result (operation state of each home appliance) of state estimation supplied from the state estimation section 212. The model parameter φ includes initial probability, distribution, and characteristic waveform W^{(m)}.

The model learning section 214 performs waveform disaggregation learning to obtain (update) the current waveform parameter as a model parameter, using current waveform Yₜ supplied from the data acquisition unit 211, and operation state of each home appliance supplied from the state estimation section 212, and updates the current waveform parameter W^{(m)} stored in the model storage unit 213, by the current waveform parameter obtained by waveform disaggregation learning.

The model learning section 214 performs disaggregation learning to obtain (update) the distribution parameter as a model parameter, using current waveform Yₜ supplied from the data acquisition unit 211, and operation state of each home appliance supplied from the state estimation section 212, and updates distribution parameter C stored in the model storage unit 213, by the distribution parameter obtained by distribution learning thereof.

The model learning section 214 performs state change learning to obtain (update) the initial state parameter as model parameter φ, and a state change parameter, using operation state of each home appliance supplied from the state estimation section 212, and updates each of the initial state parameter stored in the model storage unit 213 and the state change parameter, by the initial state parameter obtained by the state change learning and the state change parameter. HMM can be used as an overall model stored in the model storage unit 213. The data output section 216 obtains and displays, on a display apparatus or the like, consumption power of home electrical appliances represented by respective home electrical appliance models using the overall model stored in the model storage unit 213.

As further related technology, in Patent Literature 4, current waveform data is extracted, which is obtained by averaging total load current for one cycle of commercial power supply frequency, based on total load current and voltage measured at a prescribed position in a service wire of a customer area, and convex point information is extracted that relates to a convex point indicating a point where change in current value turns from increase to decrease, or a point of turning from decrease to increase, from the averaged current waveform data. The estimation section stores in advance an estimation model associating a type of an electrical device with convex point information and consumption power. The estimation section individually estimates consumption power of an electrical device being operated, based on convex point information extracted by the data extraction unit and estimation model.

Patent Literature 5 discloses a power estimation apparatus that receives current waveform and voltage waveform measured for an electrical device that consumes power from one or a plurality of power sources and estimates consumption power of the electrical device from the current waveform of the electrical device, includes a power estimation section that estimates electrical power for each electrical device based on data of the received current waveform and voltage waveform; a holding unit that holds power consumption patterns representing characteristics of consumption power and change amount of the consumption power, for each electrical device; and an estimation power correction unit that decides whether or not the electrical power estimated by the electrical power estimation section matches the electrical power consumption pattern held by the holding unit, and in a case where it is decided that there is no match, corrects the electrical power according to the electrical power consumption pattern.

An apparatus consumption electrical power estimation apparatus disclosed in Patent Literature 6 includes a device feature learning section, a device feature database, an operation state estimation section, and a consumption power estimation section. The device feature learning section obtains a feature value of an operation state of an apparatus from electrical current or power frequency obtained from time series data of voltage and current measured in a power supply path. The device feature database stores the obtained feature value of the operation state of the apparatus. The operation state estimation section estimates the operation state of the device based on harmonics feature values obtained from harmonics of electrical current or power, and a feature value(s) of operation state of the device stored in the device feature database. The consumption power estimation section estimates consumption power of the device based on the estimation operation state.

It is noted that for the FHMM, EM algorithm, Gibbs-Sampling and the like, Non-Patent Literature 1 for example may be referred to.

### CITATION LIST

### Patent Literature

[PTL 1] Japanese Patent Kokai Publication No. JP2000-292465A
[PTL 2] Japanese Patent Kokai Publication No. JP2013-213825A
[PTL 3] Japanese Patent Kokai Publication No. JP2013-218715A
[PTL 4] Japanese Patent Kokai Publication No. JP2011-232061A
[PTL 5] Japanese Patent Kokai Publication No. JP2015-102526A
[PTL 6] Japanese Patent Kokai Publication No. JP2016-017917A

### Non-Patent Literature

[NPL 1] Zoubin Ghahramani and Michael I. Jordan, “Factorial Hidden Markov Models”, Machine Learning Volume 29, Issue 2-3, November/December 1997
[NPL 2] Deep Learning for Natural Language Processing, Danushka Bollegala, (in Japanese) Japanese Society for Artificial Intelligence Journal, Vol. 27 No. 4 X (2012), <Internet Search: 2016/09/01, URL: https://cgi.csc.liv.ac.uk/˜danushka/papers/DeepNLP.pdf>

### SUMMARY

### Technical Problem

An analysis of the related technology is given below. In the above described related technology that relates to waveform disaggregation, it is not possible, for example, to perform waveform disaggregation for a plurality of units with identical or substantively identical configuration. Or, even if waveform disaggregation can be performed, accuracy may be reduced. As in a production line, for example, it is a fact that there is no example of application of waveform disaggregation to a case (system) where there are a plurality of devices of the same type.

Accordingly, the present invention was invented in consideration to the above described issues, and it is an object thereof to provide a waveform disaggregation apparatus, a method and a program, each enabling to disaggregate, from a composite signal waveform, signal waveforms between units of identical or substantively identical configuration, for example.

### Solution to Problem

According to an aspect of the present invention there is provided a waveform disaggregation apparatus comprising:

a storage apparatus that stores, as a model of an operation state of a unit, a first state transition model including a segment in which each state transition occurs along a one directional single path; and

an estimation section that receives a composite signal waveform of a plurality of units including a first unit that operates based on the first state transition model,

the estimation section performing, at least based on the first state transition model, estimation of a signal waveform of the first unit from the composite signal waveform to separate the signal waveform therefrom.

According to an aspect of the present invention there is provided a computer-based waveform disaggregation method comprising:

regarding a composite signal waveform of a plurality of units including a first unit that operates based on a first state transition model, the first state transition model including a segment in which each state transition occurs along a one directional single path,

performing, based on the first state transition model, estimation of a signal waveform of the first unit from the composite signal waveform to separate the signal waveform therefrom.

According to an aspect of the present invention there is provided a program that causes a computer to execute processing comprising:

receiving a composite signal waveform of a plurality of units including a first unit that operates based on a first state transition model, the first state transition model including a segment in which each state transition occurs along a one directional single path; and

performing, based on the first state transition model, estimation of a signal waveform of the first unit from the composite signal waveform to separate the signal waveform therefrom. According to the present invention, there is provided a computer readable storage medium that stores the above described program (for example, a non-transitory computer readable recording medium such as semiconductor storage such as RAM (Random Access Memory), ROM (Read Only Memory), EEPROM (Electrically Erasable and Programmable ROM) or the like, a HDD (Hard Disk Drive), CD (Compact Disc), DVD (Digital Versatile Disc) or the like).

According to another aspect of the present invention, the waveform disaggregation apparatus may be configured to include an estimation section that estimates and disaggregates a signal waveform of a plurality of units from a composite signal waveform of the plurality of units, and an anomaly estimation section that receives a signal waveform disaggregated for each unit by the estimation section, calculates anomaly level indicating a degree of anomaly, from the signal waveform or a prescribed state to detects an anomaly of the unit.

### Advantageous Effects of Invention

According to the present invention, it is possible, for example, to separate a signal waveform between units having identical or substantively identical configurations, from a composite signal waveform.

### BRIEF DESCRIPTION OF THE DRAWINGS

FIG. 1 is a diagram illustrating a configuration of an exemplary embodiment of the present invention.

FIG. 2A is a diagram illustrating an exemplary embodiment of the invention.

FIG. 2B is a diagram illustrating an exemplary embodiment of the invention.

FIG. 2C is a diagram illustrating an exemplary embodiment of the invention.

FIG. 3 is a diagram illustrating a comparative example.

FIG. 4 is a diagram illustrating an exemplary embodiment of the invention.

FIG. 5 is a diagram illustrating an exemplary embodiment of the invention.

FIG. 6 is a diagram illustrating an example of a system configuration of a first exemplary embodiment of the invention.

FIG. 7 is a diagram illustrating an example of a device configuration of the first exemplary embodiment of the invention.

FIG. 8 is a diagram illustrating the first exemplary embodiment of the invention.

FIG. 9 is a diagram illustrating the first example embodiment of the invention.

FIG. 10A is a schematic plan view describing a mounter configuration to which the first example embodiment of the invention is applied.

FIG. 10B is a diagram illustrating a 2-stage model of a mounter.

FIG. 11 is a diagram illustrating a composite current waveform and a disaggregated waveform in a specific example of the first example embodiment of the invention.

FIG. 12 is a diagram illustrating a composite current waveform in a specific example of the first example embodiment of the invention.

FIG. 13 is a diagram illustrating a composite current waveform and a disaggregated waveform in a specific example of the first example embodiment of the invention.

FIG. 14 is a diagram illustrating a specific example of the first example embodiment of the invention.

FIG. 15 is a diagram illustrating a specific example of the first example embodiment of the invention.

FIG. 16 is a diagram illustrating an example of a device configuration of a second example embodiment of the invention.

FIG. 17A is a diagram illustrating an example of a device configuration of a third example embodiment of the invention.

FIG. 17B is a diagram illustrating an example of a transition model of an operational state of the third example embodiment of the invention.

FIG. 18 is a diagram illustrating an example of a device configuration of a fourth example embodiment of the invention.

FIG. 19 is a diagram illustrating related technology (Patent Literature 2) for waveform disaggregation.

FIG. 20 is a diagram illustrating an example of a device configuration of a fifth example embodiment of the invention.

FIG. 21 is a diagram illustrating an anomaly estimation section in the fifth example embodiment of the invention.

### DESCRIPTION OF EMBODIMENTS

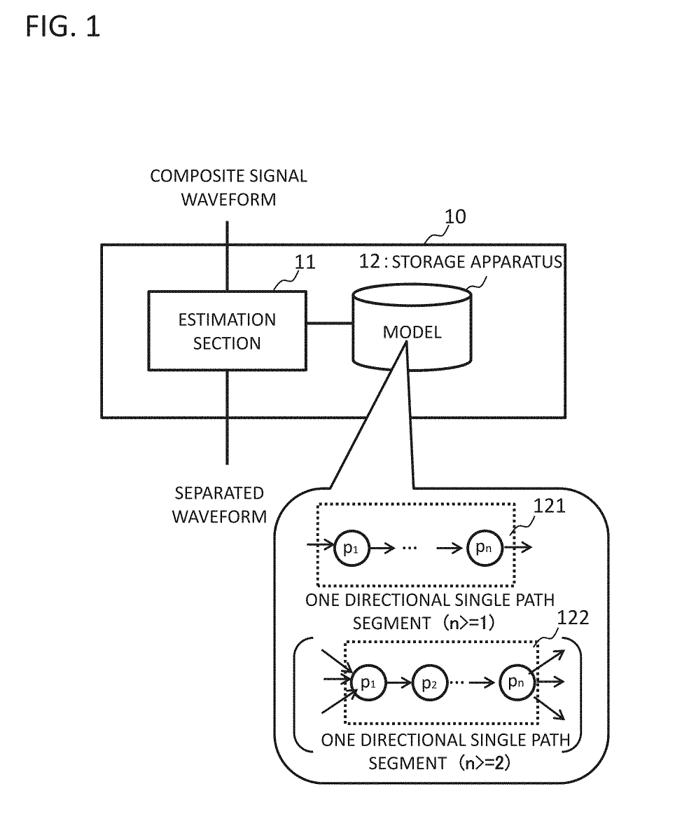

The following describes one of modes of the present invention. FIG. 1 is a diagram illustrating a basic embodiment of the present invention. Referring to FIG. 1, a waveform disaggregation apparatus 10 includes: a storage apparatus 12 (memory) that stores, as a model of an operation state of a unit, a first state transition model including a segment in which a transition occurs along a single path with one direction (state transition path: single path), and an estimation section 11 (processor) that receives, as an input, a measurement result of a composite signal waveform of a plurality of units including a first unit operating under a constraint of the first state transition model, and that at least based on the first state transition model, performs estimation of a signal waveform of the first unit from the composite signal waveform to separate the signal waveform of the first unit from the composite signal waveform. The model stored in the storage apparatus 12 may include a factor(s) of a Factorial HMM.

According to the embodiment of the present invention, as illustrated schematically in a model 121 of FIG. 1, the single path segment along one direction includes at least a state with one edge input to the state (node) and with one edge exiting from the state (node) (corresponding to the model 121, where n≥1 in of FIG. 1). That is, in the single path segment along one direction, when a state is a first state (for example, p₁ in the model 122 of FIG. 1) at a certain time, a transition occurs to a second state (p₂ in the model 122 of FIG. 1) with transition probability 1 at a next time. It is noted that a segment with the number of states n≥1 in the model 121 of FIG. 1, and a segment with the number of states n≥2 in the model 122 in parentheses (there exists one state transition path along one direction from state p₁ with input of a plurality of edges to state p₂) are equivalent.

According to an example embodiment of the present invention, the plurality of units include a second unit identical or of identical type as the first unit, and the estimation section 11 may be configured to disaggregate a composite signal waveform of the first and second units into a signal waveform of the first unit and a signal waveform of the second unit, based on the first state transition model of the first unit and a state transition model of the second unit.

According to an example embodiment of the present invention the first and second units may be any of:

first and second units provided within one equipment configuring one production line,

first and second facilities configuring one production line, and

a first unit of a first equipment configuring a first production line and a second unit of a second equipment configuring a second production line. Alternatively, the first and second unit may be first and second personal computers (PCs) of identical or substantively identical configuration (first and second home electrical appliances).

According to an example embodiment of the present invention, a signal, a waveform of which is subjected to disaggregation may be electrical current, voltage, power or the like.

According to an example embodiment of the present invention, it is possible to disaggregate waveforms of the first unit and the second unit from a composite waveform of the plurality of units including at least the first unit with operational constraint imposed thereto and a second unit identical or of a substantively identical configuration to the first unit.

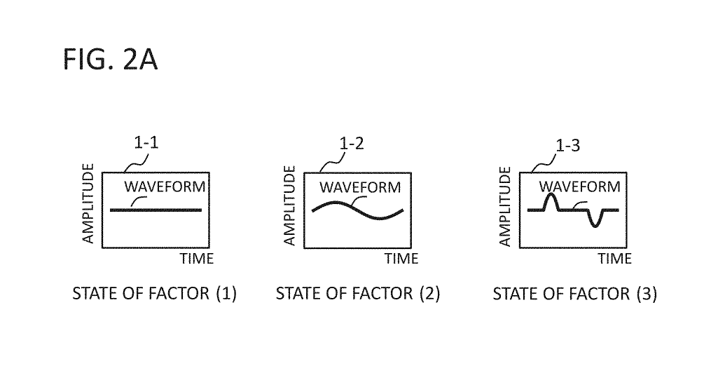

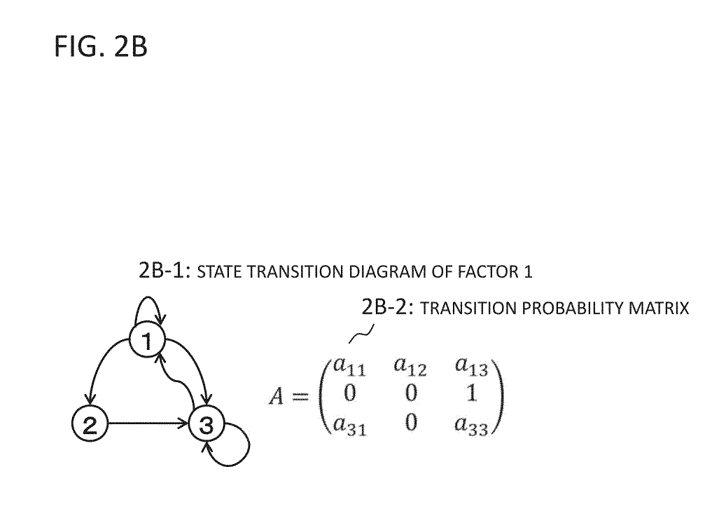

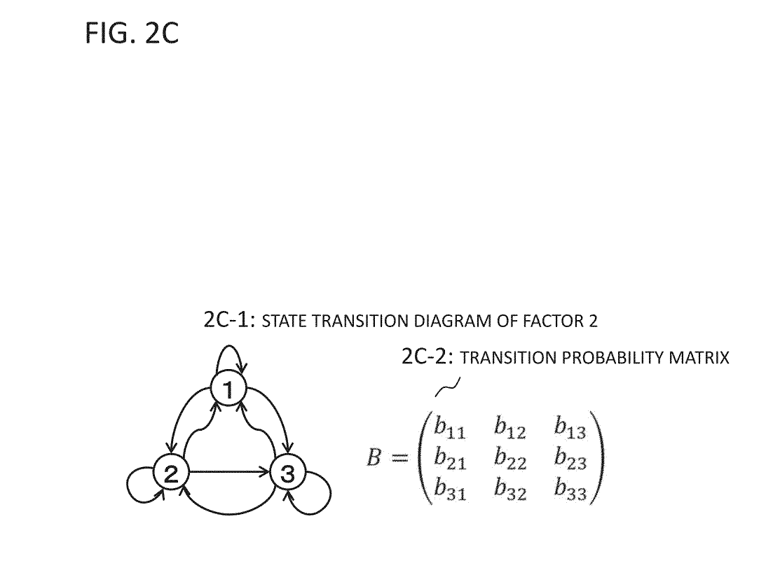

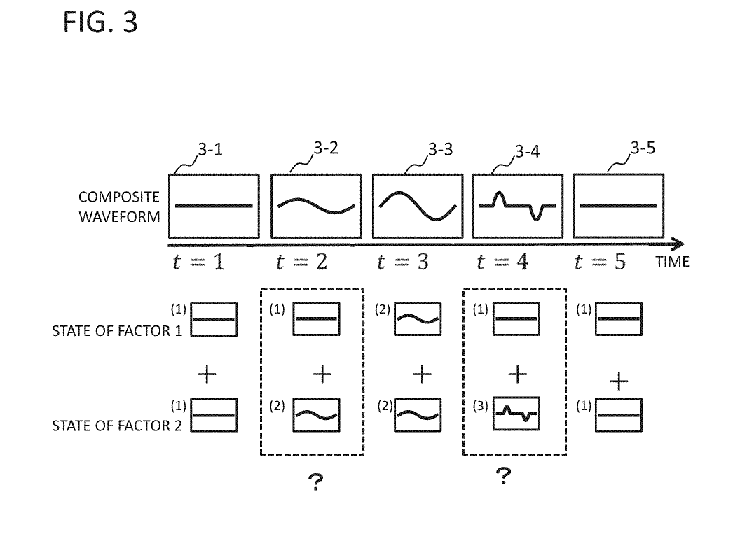

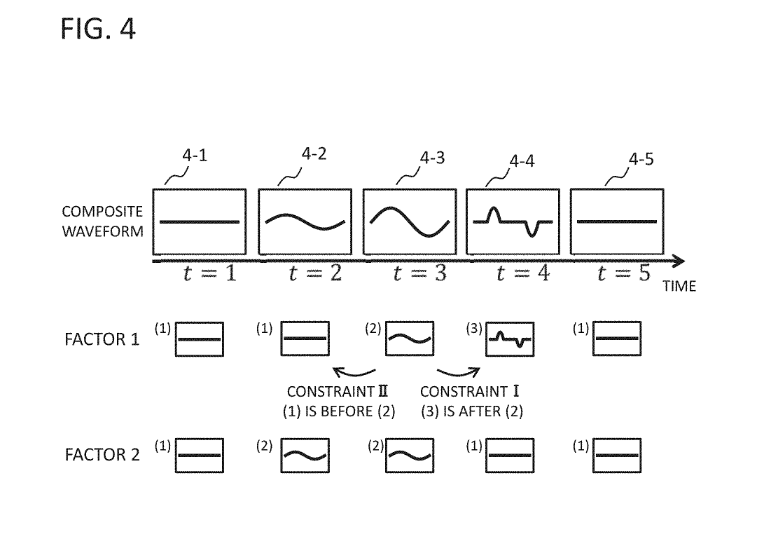

Next, referring to FIG. 2A to FIG. 2C, FIG. 3 and FIG. 4, a description is given of an operation of estimating a waveform in the example embodiment of the present invention which has been described with reference to FIG. 1. It is assumed that there are two factors from three states (factors 1 and 2 correspond respectively to the first and second units), wherein the factors 1 and 2 have the same configuration and instantaneous waveforms thereof are the same.

In FIG. 2A, 1-1, 1-2 and 1-3 are signal waveform (for example, current waveforms) of respective factors for factor states (1), (2) and (3). In FIG. 2A:

1-1 represents a waveform (holding a constant level) of a stop state (state (1));
1-2 represents a waveform of a certain work operation (state (2)); and
1-3 represents a waveform of another work operation (state (3)). It is noted that in the respective waveforms 1-1 to 1-3 of FIG. 2A, a horizontal axis represents time and a vertical axis represents amplitude (current value in the case of current, for example).

Here, constraint I and constraint II are imposed on factor 1. However, only one of either constraint I and constraint II may be imposed.

Constraint I: when in state (2) at a certain time t, at a next time t+1, in state (3).

Constraint II: when in state (2) at a certain time t, at a previous time t−1, in state (1).

FIG. 2B illustrates an example of a state transition diagram (2B-1) and a transition probability matrix A (2B-2) for factor 1. As an example of constraint I, in the state transition diagram (2B-1) for factor 1, as illustrated in FIG. 2B, there is only one arrow coming out from state (2) toward state (3). There is only one non-zero column element a₂₃ (element in row 2 column 3: value 1) in the second row of the transition probability matrix A (2B-2).

As an example of constraint II, as illustrated in FIG. 2B, in the state transition diagram (2B-1) for factor 1, there is only one arrow coming out from state (1) toward state (2). There is only one non-zero element a₁₂ (element in row 1 column 2) in the second column of the transition probability matrix A (2B-2).

FIG. 2C illustrates an example of a state transition diagram (2C-1) and a transition probability matrix B (2C-2) for factor 2. There is no one directional single path between state (2) and state (3). There is no one directional single path between state (1) and state (2). In state (2) at a certain time t, at the previous time t−1, state (1), state (2) or state (3) exist (elements b₁₂, b₂₂, b₂₃ of the second row of the transition probability matrix B are non-zero).

FIG. 3 is a diagram illustrating a comparative example (an example that does not adopt the arrangement of the above described example embodiment). 3-1 to 3-5 in FIG. 3 are composite waveforms for factor 1 and 2, observed at respective sampling times (t=1, 2, 3, 4, 5). With the respective waveforms 3-1 to 3-5, at respective sampling times (t=1, 2, 3, 4, 5), combinations of states of factor 1 and factor 2 corresponding to respective composite waveforms are shown. In the combinations of states of factor 1 and factor 2 in FIG. 3, (1), (2) or (3), at top left of the waveform indicate that the waveform is one of state (1), (2) or (3).

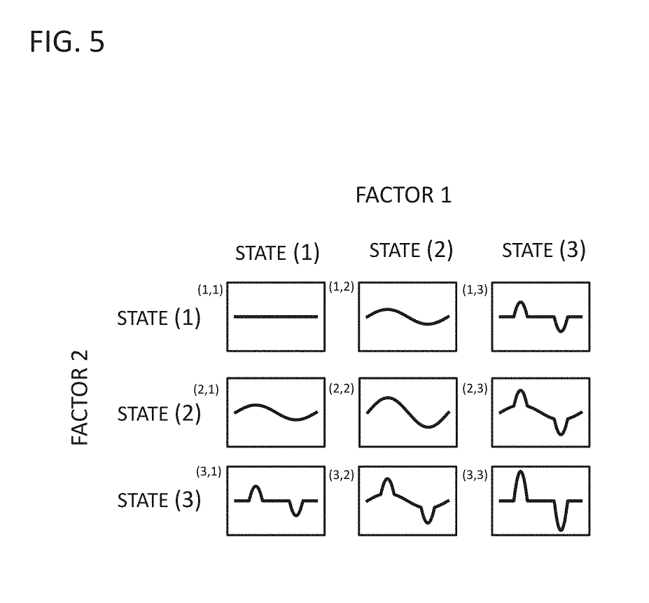

It is noted that correspondence of combination (3×3) of states (1) to (3) of factor 1 and factor 2 and composite waveforms is as schematically illustrated in FIG. 5. FIG. 5 represents that (i, j) attached to 3×3 composite waveforms represents a composite waveform when states of factors 1 and 2 are respectively #j and #i (where i=1 to 3, and j=1 to 3).

In FIG. 3 from looking only at waveform, it is understood that, at time t=2, there are combinations of (1) and (2) as states of factor 1 and 2. However, when performing waveform disaggregation of a composite waveform at time t=2, as illustrated in the example of FIG. 5, there exists a possibility to have two cases: a case where factor 1 is in state (1) and factor 2 is in state (2), and a case where factor 1 is in state (2) and factor 2 is in state (1). At time t=2, from only an analysis of waveform, it is not known which of factor 1 and factor 2 is in state (1) and which is in state (2).

Similarly, at time t=4, it is understood that there exists a combination of states (1) and (3) as states of factor 1 and 2. However, it is not known which of factor 1 and factor 2 is in state (1) and which is in state (3).

On the other hand, as in an example embodiment of the present invention, in a case of a constraint on state transition, as illustrated in FIG. 4, at time t=2, it is known which of the respective states of factor 1 and factor 2 is in state (1) or in state (2). At time t=4, it is known which of the respective states of factor 1 and factor 2 is in state (1) or in state (3). It is noted that composite waveforms 4-1 to 4-5 at respective times in FIG. 4 are identical to composite waveforms 3-1 to 3-5 at respective times in FIG. 3.

Referring to FIG. 4, for example, at time t=3, it is confirmed that both factor 1 and 2 are in state (2). Here, as for factor 1, due to constraint II imposed on factor 1, state (1) exists before state (2). Therefore, in the estimation section 11 of FIG. 1, it is confirmed that state at time t=2 for factor 1 is state (1). Therefore, factor 2 at time t=2 is in state (2).

Due to constraint I on factor 1, since state (3) exists at time after state (2), it is confirmed that factor 1 at time t=4 is in state (3). Therefore, factor 2 at time t=4 is in state (1). It is noted that correspondence between composite waveforms and factor 1 and 2 states, shown schematically in FIG. 5, may be stored and held in a storage apparatus 12.

In this way, according to an example embodiment of the present invention, by introducing a constraint to a state transition, it is possible to confirm a state of each of units which have identical configuration.

Using the above described constraints is advantageous with regard to amount of computation, description of which is given later.

Above a description has been given of configuration and operational principles of an example embodiment of the present invention. Below, a description is given of several example embodiments.

### First Example Embodiment

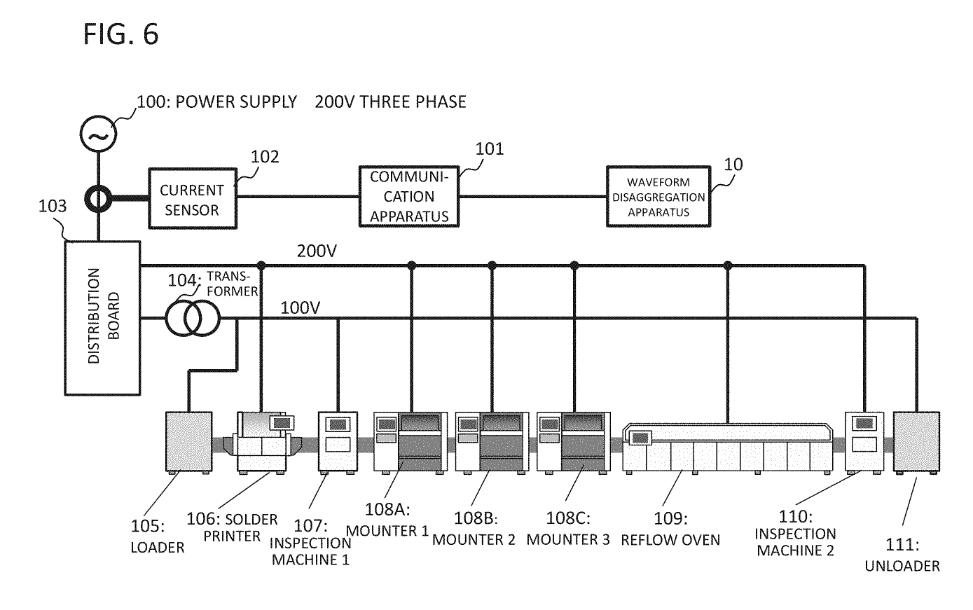

FIG. 6 illustrates a production line as an example of a system configuration of a first example embodiment. In the first example embodiment, a description is given of application to an SMT (Surface Mount Technology) line as a production line, though the present invention is not limited thereto.

Referring to FIG. 6, a loader (substrate feeder) 105 feeds a substrate (production substrate) set in a rack, to a solder printer 106. The solder printer 106 transfers (prints) cream solder using a metal mask on a substrate pad. An inspection machine 1 (107) inspects an exterior appearance of the solder printed substrate. Mounter 1 (108A) to mounter 3 (108C) automatically mount surface mount components on the substrate printed with cream solder. A reflow oven 109 heats the substrate for which mounting has been completed, by using upper and lower heaters in the oven, melts the solder, and fixes components to the substrate. An inspection machine 2 (110) inspects the exterior appearance. An unloader 111 automatically houses the substrate on which soldering has been completed, into a substrate rack (not shown in the drawings).

A current sensor 102 measures power supply current (composite power supply current of respective facilities of the production line) of, for example, the main flow of a distribution board 103. The current sensor 102 transmits measured current waveform (digital signal waveform) via a communication apparatus 101 to a waveform disaggregation apparatus 10. The current sensor 102 may be configured by a CT (Current Transformer) (for example, Zero-phase-sequence Current Transformer: ZCT)) or a Hall element. The current sensor 102 may perform sampling of current waveform (analog signal) by an analog digital transformer which is not illustrated, and transform the sampled signal to a digital signal waveform, and perform compression coding by an encoder which is not illustrated, to perform wireless transmission of the compression coded data to the communication apparatus 101 by a W-SUN (Wireless Smart Utility Network) or the like.

It is noted that the communication apparatus 101 may be arranged in a factory (building). The waveform disaggregation apparatus 10 may be arranged inside a factory or may be implemented on a cloud server connected with the communication apparatus 101 via a wide area network such as the Internet.

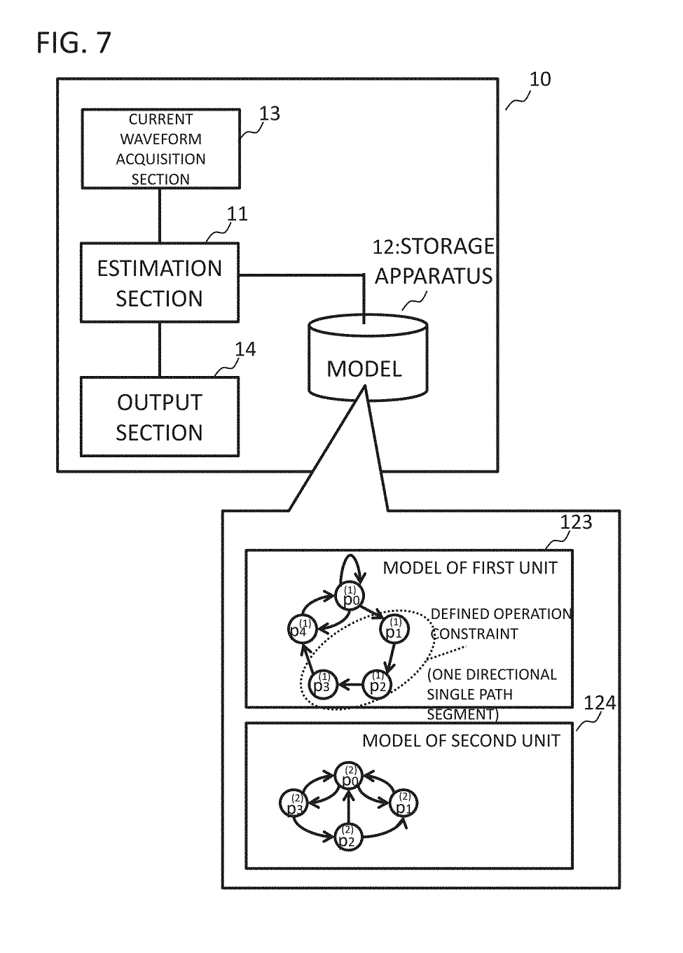

FIG. 7 is a diagram illustrating an example of a configuration of the waveform disaggregation apparatus 10 of FIG. 6. In FIG. 7, a current waveform acquisition section 13 obtains a power supply current waveform (composite current waveform of a plurality of devices) obtained by the current sensor (102 in FIG. 6). The current waveform acquisition section 13 may include a communication unit which is not illustrated and may obtain a composite current waveform from a current sensor via the communication apparatus 101 of FIG. 6. Alternatively, the current waveform acquisition section 13 may read out a waveform that is stored in advance in a storage apparatus (waveform database or the like) which is not illustrated, to obtain a composite current waveform.

The storage apparatus 12 stores state transition models that model transitions of operation states for respective devices (for example, loader 105, unloader 111, solder printer 106, inspection machines 1, 2 (107, 110), mounters 108A to 108C, reflow oven 109) that configure the line of FIG. 6. A model combining state transitional models of a plurality of units may, for example, form a Factorial HMM model.

It is noted that in the first example embodiment, where an equipment has identical plural units, in order to perform waveform disaggregation thereof, a state transition model of at least one unit (first unit) includes a model corresponding to a state transition diagram including a one-directional single path segment.

An estimation section 11 estimates and performs estimation and disaggregation of respective power supply current waveforms of respective units, based on a state transition model stored in the storage apparatus 12, with respect to a composite power supply current obtained by the current waveform acquisition section 13.

It is noted that in FIG. 7, circles around models (state transition models) 123 and 134 stored in the storage apparatus 12 represent unobserved (hidden) states {Sₜ}. For example, regarding a state variable Sₜ at time t, there are a plurality (M): Sₜ⁽¹⁾, Sₜ⁽²⁾ . . . , Sₜ^{(m)}, from factor 1 to factor M, and one item of observation data Yₜ is generated from these plural state variables of Sₜ⁽¹⁾ to Sₜ^{(m)}. The M state variables Sₜ⁽¹⁾ to Sₜ^{(m)} correspond to M units, and a state value of the state variable Sₜ^{(m)} represents an operation state of a unit, for example. It is noted that the m-th state variable Sₜ^{(m)}, is also referred to as the m-th factor or factor m.

In model 123 of the first unit, for a one-directional single path segment (state p₁⁽¹⁾ to p₃⁽¹⁾), the state of the first unit corresponds to an operation constraint of the first unit that when the state (hidden state Sₜ⁽¹⁾) at a time t is p₁⁽¹⁾, the state (hidden state Sₜ₊₁⁽¹⁾) at a next time t+1, is p₂⁽¹⁾ with transition probability=1. It is noted that (1) on a shoulder of operation state p₁⁽¹⁾ represents factor 1, notation of which corresponds to (1) on a shoulder of state variable Sₜ⁽¹⁾ and (2) on a shoulder of operation state p₁⁽²⁾ of the model 124 of the second unit represents factor 2, notation of which corresponds to (2) in the shoulder of state variable Sₜ⁽²⁾.

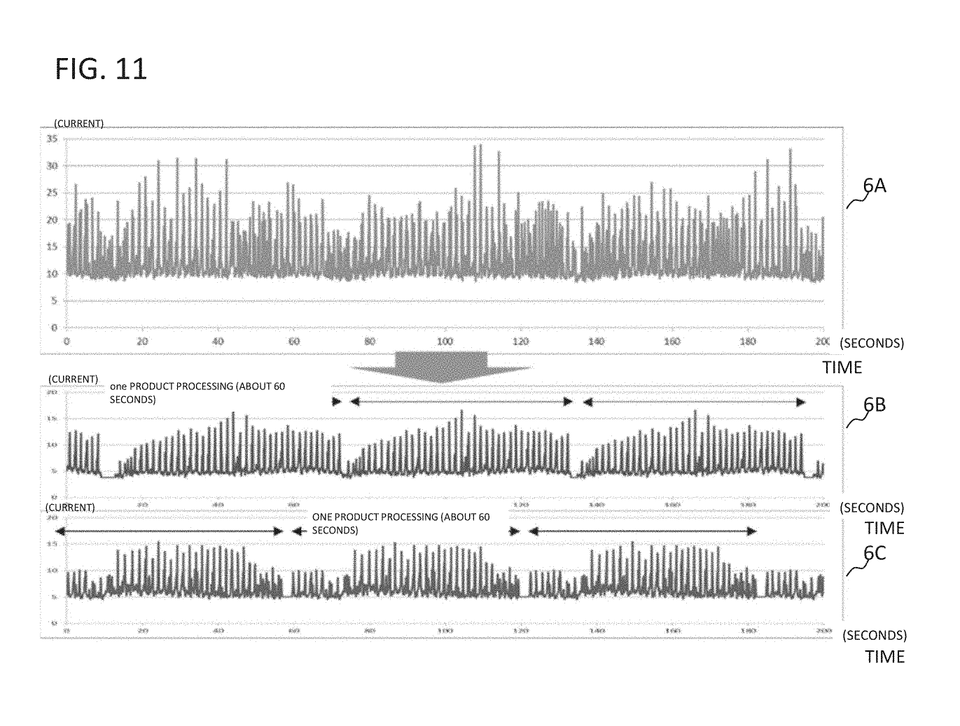

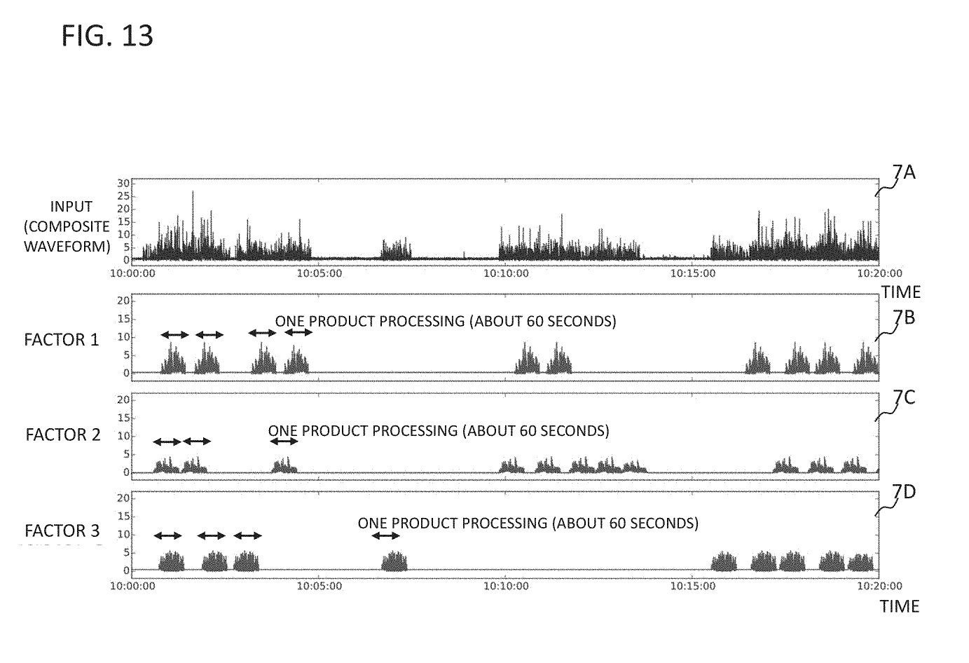

An output section 14 outputs current waveforms of respective units for which estimation and disaggregation have been performed by an estimation section 11 (FIG. 11 and FIG. 13 described later). The output section 14 may obtain power consumption to display on a display apparatus, based on operation state and disaggregation current waveform of the units. The output section 14 may transmit current waveform and power of the units to be displayed, to a terminal connected via a network not illustrated.

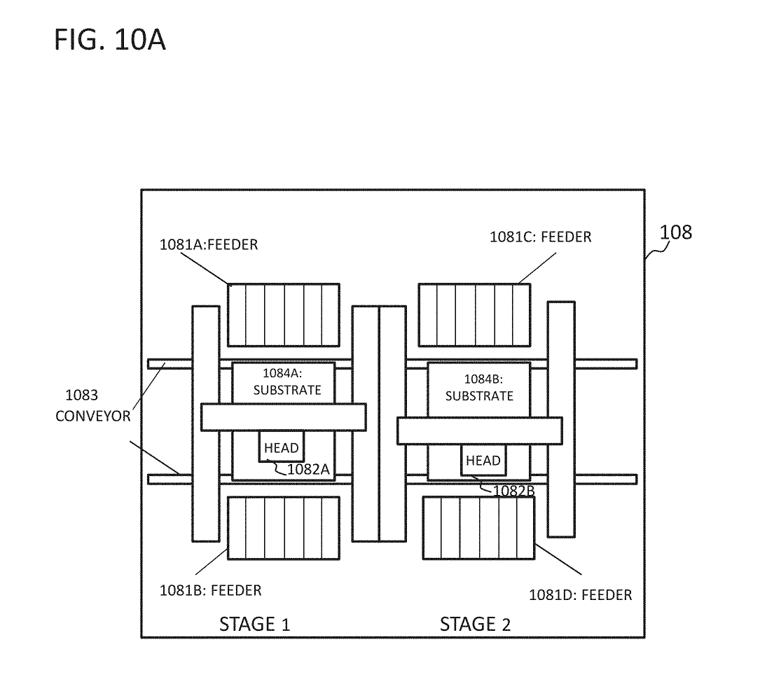

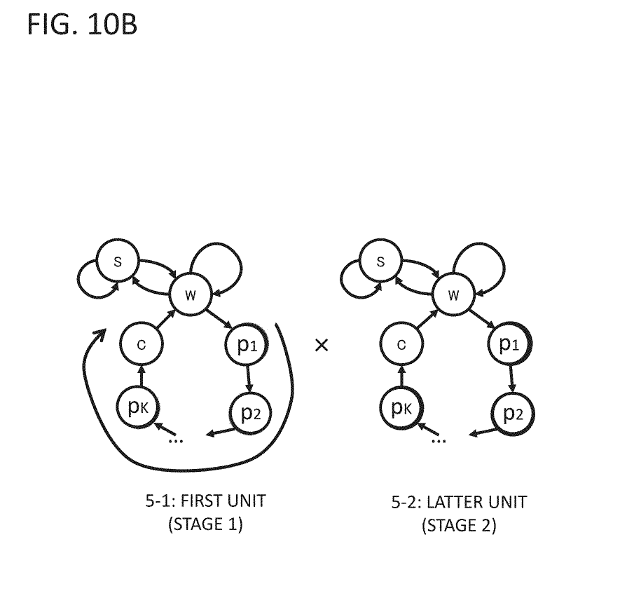

In the first example embodiment, a unit which is a target for estimation and disaggregation of current waveform and on which an operation constraint is imposed (state transition model includes one directional single path segment), may, in a case where an equipment (e.g., a mounter) of FIG. 6 include a plurality of units (for example, a plurality of units of identical configuration), be the units in question, which will be later described with reference to FIG. 10. Alternatively, a unit which is a target for estimation and disaggregation of current waveform and on which an operation constraint is imposed, may be a facility (equipment). Alternatively, the unit in question may be an entirety of a production line (for example, an entire SMT line of FIG. 6). Alternatively, the unit in question may be a combination of unit a of a facility A, and unit b of a facility B. Alternatively, the unit in question may be each of home electric appliances such as identical personal computers or the like.

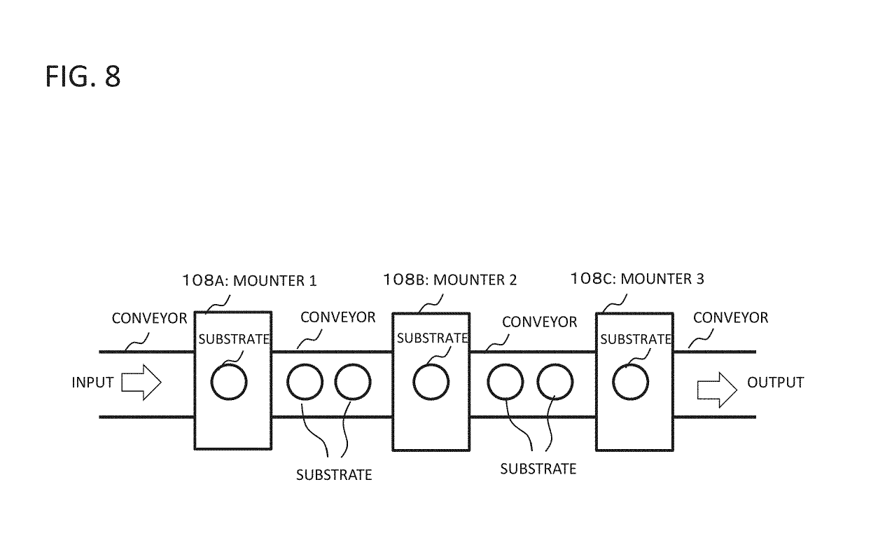

FIG. 8 is a diagram illustrating an operation model of 3 mounters 1, 2 and 3 (108A-108C) in the SMT line of FIG. 6. Each mounter is represented as a queueing network. A mounter has a role of service station; a conveyor between mounters has a role of buffer (queueing). When a substrate arrives, the mounter performs a processing operation to mount components on the substrate in accordance with a program and then outputs the substrate. The substrate output from the mounter is delivered to a facility (equipment) (next mounter or reflow oven) in a succeeding stage by a conveyor. When a buffer on an output side of the mounter becomes full (buffer overflow), a buffer on an input side is empty (buffer empty), or the mounter itself has some sort of error (for example, broken chip), processing stops.

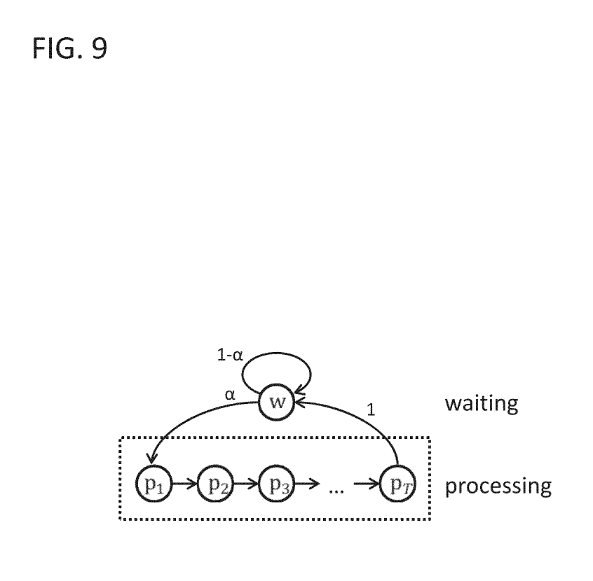

FIG. 9 is a diagram illustrating a model representing operations of the mounter of FIG. 8. “Processing” represents that the mounter is processing a substrate. “waiting: w” (waiting state) represents the mounter waiting for previous or succeeding process (waiting for arrival of a substrate from previous process, or waiting to export the substrate to a succeeding process) or waiting for error recovery. In FIG. 9, time required for one cycle, as from state W, via state p₁ to p_{T}, to return to the state W, is referred to as a cycle time.

State transition probability P(Sₜ|Sₜ₋₁) between states is given as below.

P(Sₜ=pₖ|Sₜ₋₁=pₖ₋₁)=P(Sₜ=w|Sₜ₋₁=p_{T})=1 (1)

P(Sₜ=p₁|Sₜ₋₁=w)=α (2)

P(Sₜ=w|Sₜ₋₁=w)=1−α (3))

The above equation (1) indicates that when a value (operation state) of state variable Sₜ₋₁ at time t−1 is pₖ₋₁, a probability that a value (operation state) of state variable Sₜ at subsequent time t transitions to pₖ is 1 (k=1 to T), and when a value (operation state) of state variable Sₜ₋₁ at time t−1 is p_{T}, a probability that a value (operation state) of state variable Sₜ at subsequent time t transitions to W is 1.

The above equation (2) indicates that when a value (operation state) of state variable Sₜ₋₁ at time t−1 is w (waiting state), a probability that a value (operation state) of state variable Sₜ at subsequent time t, transitions to p1, is α (0<α<1).

The above equation (3) indicates that when a value (operation state) of state variable Sₜ₋₁ at time t−1 is w (waiting state), a probability that a value (operation state) of state variable Sₜ at subsequent time t transitions to w, is 1−α.

In the first example embodiment, in estimating and learning of current waveform parameters of a unit (factor) using an operation state model (state transition model) of a unit stored in the storage apparatus 12, it is, as a matter of course, possible to use, as disclosed in Non-Patent Literature 1, an EM algorithm, Gibbs sampling, Completely Factorized Variational Inference, Structured Variational inference or the like. Among these, Patent Literature 3 describes an example of estimation processing of current waveform parameters and the like using Completely Factorized Variational Inference, Structured Variational Inference. In Patent Literature 3, Structured Variational Inference is described as an example of E step, and in M step corresponding to this, Completely Factorized Variational Inference is used. It is noted that in the first example embodiment for example, Structured Variational Inference may be used (refer to Non-Patent Literature 1), though not limited thereto.

In Structured Variational Inference, as described in Appendix D of Non-Patent Literature 1, a parameter hₜ^{(m)} that minimizes Kullback-Leibler divergence) KL which is a similarity measure of probability distribution, may be derived as below. It is noted that with Structured Variational Inference of Non-Patent Literature 1, Kullback-Leibler divergence KL is given below.

$$KL = {\sum }_{t = 1}^{T} {\sum }_{m = 1}^{M} 〈 {S}_{t}^{( m )} 〉 log {h}_{t}^{( m )} + \frac{1}{2} {\sum }_{t = 1}^{T} [ {Y}_{t}^{′} {C}^{- 1} {Y}_{t} - 2 {\sum }_{m = 1}^{M} {Y}_{t}^{′} {C}^{- 1} {W}^{( m )} 〈 {S}_{t}^{( m )} 〉 + {\sum }_{m = 1}^{M} {\sum }_{n \neq m}^{M} tr \{ {{W}^{( m )}}^{′} {C}^{- 1} {W}^{( m )} 〈 {S}_{t}^{( n )} 〉 〈 {S}_{t}^{{( m )}^{′}} 〉 \} + {\sum }_{m = 1}^{M} tr \{ {{W}^{( m )}}^{′} {C}^{- 1} {W}^{( m )} diag \{ 〈 {S}_{t}^{( m )} 〉 \} \} ] - log {Z}_{Q} + log Z \qquad ( 4 )$$

Z in the equation (4) is a normalized constant for posterior probability sum being 1 when an observation sequence is given, and Z_{Q} is a normalized constant of probability distribution (expression (C.1), (C.3) of Appendix C of Non-Patent Literature 1. It is noted that H({Sₜ, Yₜ}), H_{Q}({Sₜ}) are defined in expressions (C.2), (C.4) of Appendix C).

$$P ( \{ {S}_{t} \} \vert Y , φ ) = \frac{1}{Z} exp ( - H ( \{ {S}_{t} , {Y}_{t} \} ) )$$

$$Q ( \{ {S}_{t} \} \vert θ ) = \frac{1}{{Z}_{Q}} exp ( - {H}_{Q} ( \{ {S}_{t} \} ) )$$

With partial derivative of the above equation (4) with log h_{σ}^{(m)}, the following expression (5) is given.

$$\frac{\partial KL}{\partial log {h}_{τ}^{( n )}} = 〈 {S}_{τ}^{( n )} 〉 + {\sum }_{t = 1}^{T} {\sum }_{m = 1}^{M} [ log {h}_{t}^{( m )} - {{W}^{( m )}}^{′} {C}^{- 1} {Y}_{t} + {\sum }_{l \neq m}^{M} {{W}^{( m )}}^{′} {C}^{- 1} {W}^{( l )} 〈 {S}_{t}^{( l )} 〉 + \frac{1}{2} {Δ}^{( m )} ] \frac{\partial 〈 {S}_{t}^{( m )} 〉}{\partial log {h}_{τ}^{( n )}} - \frac{\partial log {Z}_{Q}}{\partial log {h}_{τ}^{( n )}} = {\sum }_{t = 1}^{T} {\sum }_{m = 1}^{M} [ log {h}_{t}^{( m )} - {{W}^{( m )}}^{′} {C}^{- 1} {Y}_{t} + {\sum }_{l \neq m}^{M} {{W}^{( m )}}^{′} {C}^{- 1} {W}^{( l )} 〈 {S}_{t}^{( l )} 〉 + \frac{1}{2} {Δ}^{( m )} ] \frac{\partial 〈 {S}_{t}^{( m )} 〉}{\partial log {h}_{τ}^{( n )}} ∵ \frac{\partial log {Z}_{Q}}{\partial log {h}_{τ}^{( n )}} = 〈 {S}_{τ}^{( n )} 〉 \qquad ( 5 )$$

With regard to hₜ^{(m)} that minimizes Kullback-Leibler divergence KL, by having content in the parentheses [ ] of above equation (5) as 0, the following equation (6a) is obtained. Note that equations (6a) and (6b) are obtained for m=1 to M (number of factors).

$${h}_{t}^{( m ) new} = exp \{ {W}^{{( m )}^{′}} {C}^{- 1} {\tilde{Y}}_{t}^{( m )} - \frac{1}{2} {Δ}^{( m )} \} \qquad ( 6 a )$$

Where, Δ^{(m)}=diagonal (W^{(m)}′C⁻¹W^{(m)}) (diagonal indicates diagonal component of matrix).

Residual ^{˜}Yₜ^{(m)} is defined as below.

$${\tilde{Y}}_{t}^{( m )} ≡ {Y}_{t} - {\sum }_{l \neq m}^{M} {W}^{( l )} 〈 {S}_{t}^{( l )} 〉 \qquad ( 6 b )$$

Parameter hₜ^{(m)} is an observation probability related to state variable Sₜ^{(m)} in Hidden Markov Model m. Using a forward and backward algorithm using this observation probability and state transition probability matrix A₁, j^{(m)}, a new set of expected value <Sₜ^{(m)}> is obtained, and feedback is made to equations (6a) and (6b).

In the example of FIG. 9, there are T+2 non-zero elements of a transition probability matrix A_{i,j}^{(m)}. Therefore, it is enough if the computational amount of respective iterations of E step in the EM algorithm is 0 (KTN) (refer to “computational amount reduction effect” described later).

With regard to state estimation of respective times, a parameter j that can best explain observation data X(Yₜ) is obtained (maximum likelihood estimation).

$${arg max}_{j} P ( {S}_{t}^{( m )} = j \vert X ) \qquad ( 7 )$$

It is noted that the expression (7) may be given as below when notation is matched to Non-Patent Literature 1.

$${arg max}_{j} P ( {S}_{t , j}^{( m )} ) \qquad ( {7}^{′} )$$

Here, supplementing the denotation, with regard to Non-Patent Literature 1, Sₜ^{(m)} used in the description of FIG. 7, or expression (4),

Sₜ^{(m)}

is represented by a vector known as “1-of-N representation” (refer to Non-Patent Literature 2). For M states, a vector of “1-of-M representation” representing state j becomes a vector in which only element j is 1 and the remainder are 0. Taking an expected value of this vector, respective elements form a vector, each element representing a probability of taking each state.

[symbol]

S_{t,j}^{(m)} [symbol] =P(S_{t,j}^{(m)}=1|X)

Here, a right side of the above equation

P(S_{t,j}^{(m)}=1|X)

corresponds to

P(Sₜ^{(m)}=j|X)

of the expression (7). That is, with regard to S_{t,j}^{(m)}, the following holds. (Probability that S_{t,j}^{(m)} is 1)=(Probability that state of factor m at time t is j)

Next, as a specific example of the first example embodiment, in the production line of FIG. 6, a description is given of an example applied to waveform disaggregation of a plurality of identical units.

FIG. 10A is a diagram schematically illustrating a plan view of an example in which a mounter (for example, mounter 1 in FIG. 8) includes a first half unit (stage 1) and a latter half unit (stage 2). With regard to the mounter 108, electronic components are mainly supplied by reel or tray; the reel is installed to a dedicated feeder, and the tray is set in a device known as a tray feeder. Substrates 1084A and 1084B are delivered by a conveyor 1083; heads (mounting heads) 1082A and 1082B absorb surface mount type electronic components from feeder parts 1081A-1081D by negative pressure, cause movement on an X-Y axis, moving to an intended place on the substrates 1084A and 1084B, and mount the surface mount type electronic components. It is noted that there are 2 heads per stage. The substrate 1084A on which components have been mounted in stage 1 has another group of components mounted in stage 2.

Here, a defined operation constraint is imposed on the first half unit, though not limited thereto. FIG. 10B is a diagram representing a state transition model (5-1) of the first half unit (stage 1) of FIG. 10A, and a state transition model (5-2) of the latter half unit (stage 2) of FIG. 10A.

In FIG. 10B, W represents a substrate waiting state of a mounter. When a substrate is delivered from a conveyor on an input side to a mounter and set in a stage, there is a transition to state p₁ and processing of a header retrieving a component from a feeder to be mounted at a prescribed position on the substrate is repeated. Assuming that respective states are made to correspond to mount processing of a single component, for example, when K components are to be mounted, K states shift along one direction with transition probability 1. That is, a one directional single path transition occurs along states p₁-p_{K} and C (Completion). The substrate on which a component mounting operation is completed in the operation state C, is emitted and delivered to a succeeding stage. When the component mounting operation on one substrate is completed, there is a transition to state W, wherein arrival of a next substrate in the stage is waited for. It is noted that in component mounting, there is also a mounter provided with a robot arm made of aluminum. A nozzle at the end of the arm absorbs a chip component on a tape feeder, for example. A transition probability matrix of an equipment of FIG. 10A can be represented as a matrix obtained by multiplying a transition probability matrix corresponding to state transition model (5-2) of FIG. 10B by a transition probability matrix corresponding to state transition model (5-1) of FIG. 10B.

An operation constraint as in the first half unit (stage 1) need not be imposed on an operation of the latter half unit (stage 2). Alternatively, an operation constraint similar to the stage 1 may, as a matter of course, be imposed on an operation of the latter half unit (stage 2). It is noted that the stages 1 and 2 may each be configured to operate independently, or they may operate in synchronization.

In FIG. 11, a waveform 6B depicts s a current waveform of the first half unit (stage 1) for which disaggregation estimation is performed using the model of FIG. 10B, from a composite current waveform 6A. It is noted that for the current waveform 6B of FIG. 11, processing of one product (about 60 seconds) corresponds to a time of states p1-pk, and c of the state transition diagram 5-1 of the first half unit (stage 1) of FIG. 10B, and a time interval between waveforms in processing one product (about 60 seconds) in the current waveform 6B of FIG. 11 corresponds to state W of the state transition diagram 5-1 of the first half unit (stage 1) of FIG. 10B.

In FIG. 11, a waveform 6C indicates a current waveform of the latter half unit (stage 2) obtained by subtracting the current waveform 6B from the composite current waveform 6A. It is noted that for the current waveform 6C of FIG. 11, processing of one product (about 60 seconds) corresponds to a time of states p1-pk, and c of the state transition diagram 5-2 of the latter half unit (stage 2) of FIG. 10B, and a time interval between waveforms in processing one product (about 60 seconds) in the current waveform 6C of FIG. 11 corresponds to state W of the state transition diagram 5-2 of the latter half unit (stage 2) of FIG. 10B.

It is noted that in a case where an operation constraint similar to the first half unit (stage 1) is imposed on an operation of the latter half unit (stage 2), it is possible to obtain a current waveform of the latter half unit (stage 2), similarly to the first half unit.

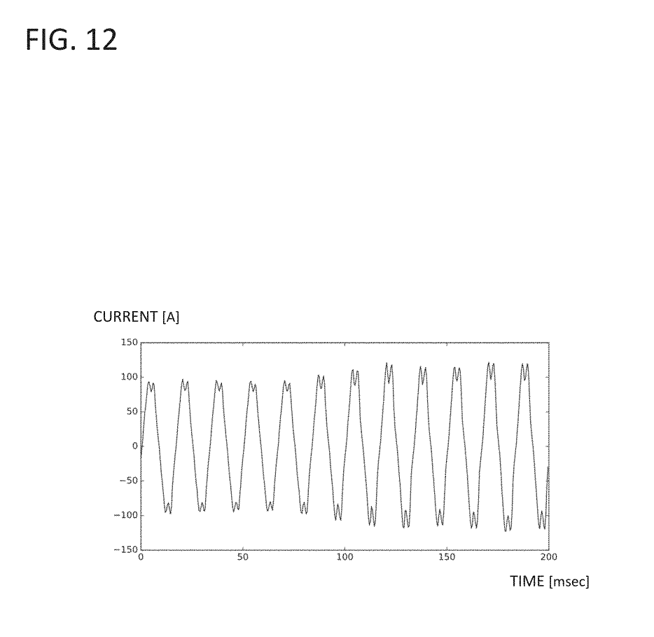

From FIG. 12, it may be understood that harmonics components appear, with a servo driver that moves a mounter arm, as a main source. Appearing as a bimodal form (2 peaks) corresponds to waveforms of harmonics components with a servo driver of the mounter, as a main source. Below, the harmonics components are extracted as a feature value of three mounters. As a specific example embodiment, a feature value of the mounters appearing as harmonics is extracted by a high pass filter. Applying a high pass FIR (Finite Impulse Response) filter, for example, to input data, root mean square value (for each 100 ms (milliseconds)) is calculated. Further applying the high pass filter, fluctuating components only are extracted. The extracted waveform is 7A in FIG. 13. A horizontal axis with regard to the waveform 7A in FIG. 13 is time. A vertical axis is root mean square value (RMS).

In FIG. 13, waveforms 7B to 7D represent current waveforms where estimation and disaggregation into three factors are performed by the estimation section 11. In FIG. 13, each horizontal axis of waveforms 7B to 7D is time in common with the horizontal axis of waveform 7A. Each vertical axis of 7B to 7D is root mean square (RMS). One repeated operation of a factor (waveform in range shown by arrows) represents one product processing (about 60 seconds). As described before, there is a correspondence with periods p₁-pₖ, and c of FIG. 10B, for example. A time interval between a mass waveform (product processing indicated by two-way arrow) and an adjacent waveform (product processing shown by two-way arrow) corresponds to a waiting state (for example, waiting state W in FIG. 10B). In 7B to 7D of FIG. 13, one product processing is about 60 seconds, though not limited thereto.

It is noted that in a case of performing waveform disaggregation machine learning for each unit (factor) in the estimation section 11 of FIG. 7, the waveform disaggregation machine learning may be performed, using an envelope with respect to signal waveforms of 7A to 7D of FIG. 13, as training waveforms, though not limited thereto.

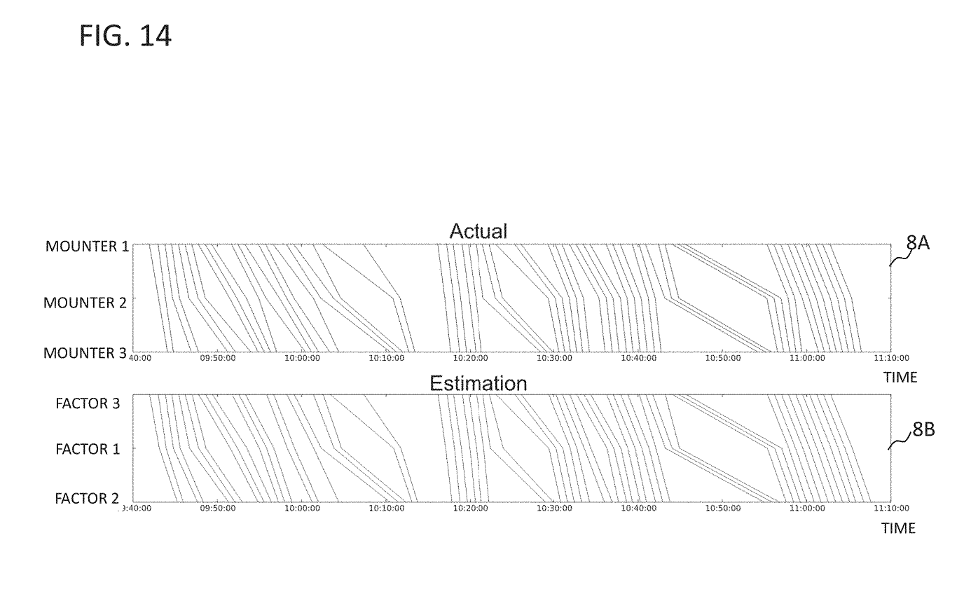

In FIG. 14, with regard to signal waveforms of factor 1 to factor 3 of 7B to 7D of FIG. 13, 8B is a schematized diagram (estimation) with end point of times of product processing connected by lines in an order of factor 3, factor 1, and factor 2. The diagram 8B corresponds to a product flow diagram. In FIG. 14, 8A indicates results (actual) collected from log data, for mounter 1, mounter 2 and mounter 3, that is, a schematic with lines connecting end point of times of product processing in an order of mounter 1, mounter 2 and mounter 3. It is noted that start point of times of product processing may also be connected by lines.

In FIG. 14, it may be understood that a situation where SMT line (mounter) is stopped, from schematics 8A and 8B. For example, a time of about 10:15 corresponds to a state (buffer empty) in which all input side buffers of the mounters 1, 2, and 3 are empty, and a time of about 10:50 corresponds to where all output side buffers of the mounters 1, 2, and 3 are full (buffer overflow). Comparing 7B and 7A, it may be understood that they match each other well.

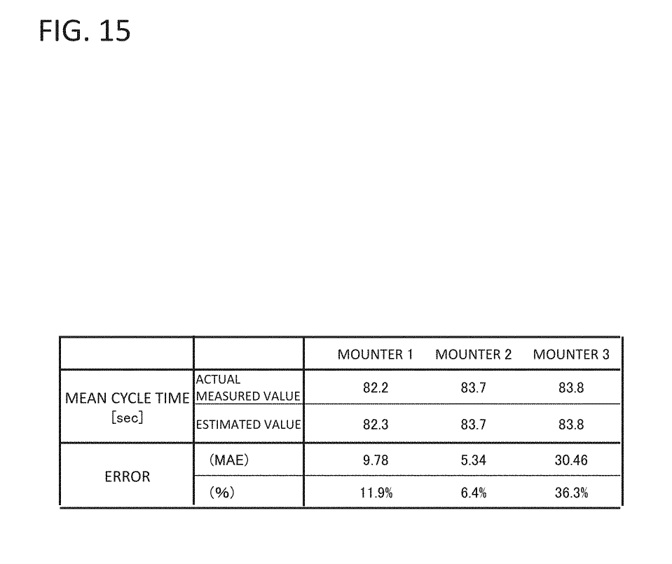

FIG. 15 illustrates an example of mean cycle time (actual measured value and estimated value) and Mean Absolute Error (MAE) of mounters 1, 2, 3. Here, cycle time represents time from starting processing of one product (substrate) by a mounter to starting processing of a next product. Mean cycle time is a mean of cycle time and is given by the following equation (8).

$$\frac{{\sum }_{i} ( Cycle time of product i )}{( number of products )} = \frac{( production time )}{( number of products )} \qquad ( 8 )$$

Therefore, MAE represents error expressing how much each cycle time of each individual product is deviated.

The first example embodiment illustrates an example of application to a technique enabling visualization of operation state of a plurality of production facilities using a single sensor, for example.

As described above, the first example embodiment is effective for improving production line efficiency.

In the first example embodiment, by applying Factorial HMM where respective factors represent cycle operations of facilities, to core current waveform data, visualization of product flow in a production line by a single sensor is made possible.

In estimating cycle time, as illustrated in FIG. 15 for example, estimation can be made with error of 6.4% (=5.34/83.7=0.06451) to 36.3% (30.46/83.8=0.3634).

According to the first example embodiment, by imposing an operation constraint on at least one unit (for example, first half unit (stage 1)), among units with identical or almost identical configuration (having a one directional single path segment in a state transition model), it is possible, for example, to disaggregate current waveforms among units with identical or almost identical configuration, from a composite current waveform of a plurality of units.

### Second Example Embodiment

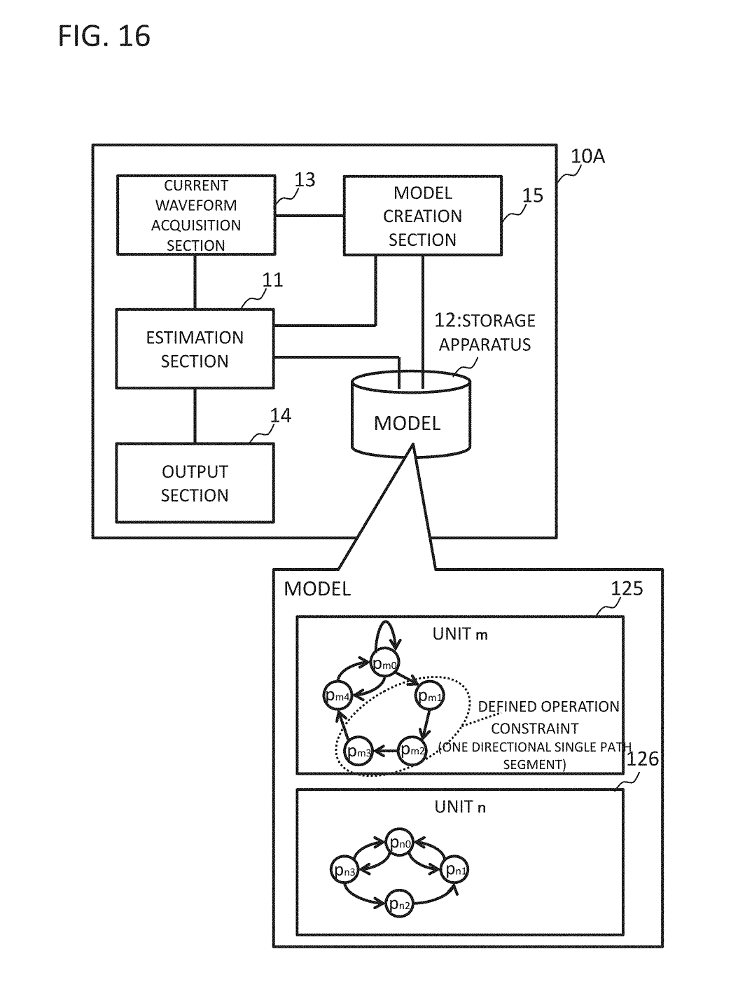

In a second example embodiment, as illustrated in FIG. 16, a model creation section 15 may include a model creation section 15 that creates a model (125, 126, etc.) to be stored in a storage apparatus 12. The model creation section 15 creates a state transition model of a unit to be stored in the storage apparatus 12, for example, by performing learning without a teacher of cluster analysis and main discriminating analysis. As a result, it is not necessary to create a model of a unit housed in the storage apparatus 12 in advance.

The model creation section 15 may have a configuration provided with a parameter learning function. The parameter learning function fixes a defined operation constraint imposed on a unit (transition state model having a one directional single path segment), and finds a solution of a parameter optimization problem, based on output of an estimation section 11, from observation data (for example, composite current waveform). A parameter to be optimized, may be a transition probability of a state transition model of a unit where a defined operation constraint is imposed.

Alternatively, the model creation section 15 may include a model structure learning function. The model structure learning function sequentially changes, for example, from an initial setting value, a structure of a fixed operation constraint (transition state model having a one directional single path segment) imposed on a unit to find a solution of an optimization problem. As the structure of the defined operation constraint to be changed, an issue may be on which state transitions, several constraints (one directional single path segment) are imposed. The fixed operation constraint(s) imposed on a unit may be changed and based on a result of estimation disaggregation of waveform by the estimation section 11 based on observation data, an operation constraint providing optimum waveform disaggregation may be determined. Models 125 and 126 of a plurality of units (unit m, and unit n: where m and n are prescribed positive integers that are different from each other) of the storage apparatus 12 illustrate state transition models of respective units created by the model creation section 15. In the model 125, state pₘ₁-pₘ₃ form a one directional single path segment corresponding to operation constraints of the unit m. It is noted that, similar to the first example embodiment, a model formed by combination of state transitional models of this plurality of units clearly may configure a Factorial HMM model.

According to the second example embodiment, model creation may be made automatic, and by parameter optimization and model learning, it is possible to improve model accuracy and to set suitable operation constraints.

### Modified Example 1

In the waveform disaggregation apparatuses 10 and 10A, output from an output section 14 may be a state string (operation state: p₁ to p_{T} in FIG. 9 for example) of a unit (factor), using a Viterbi algorithm for example, rather than power supply current waveform or power (consumption power) of a unit (factor). Alternatively, a state operation may be a time at which each unit finishes product processing, or the number of productions within a certain period of time.

### Modified Example 2

Input of waveform disaggregation apparatuses 10 and 10A may be waveform, frequency component, principal component, root mean square value, average value, power factor or the like of voltage or current. In a case other than where output is power (operation state), a signal acquisition unit that obtains input (acoustic signal, oscillation, communication amount, etc.) other than power may be provided.

In the first and second example embodiments, mainly, the application to a production line facility is described as an example, but the example embodiments of the present invention is not limited to production line facility and may be applied to domestic or enterprise personal computers (PC) or the like.

### Third Example Embodiment

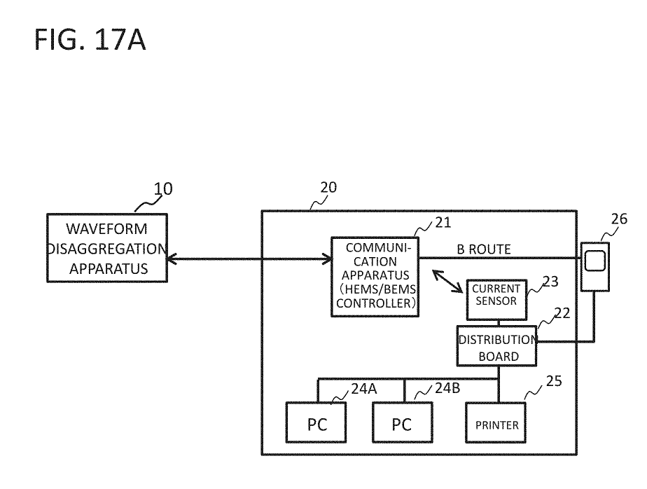

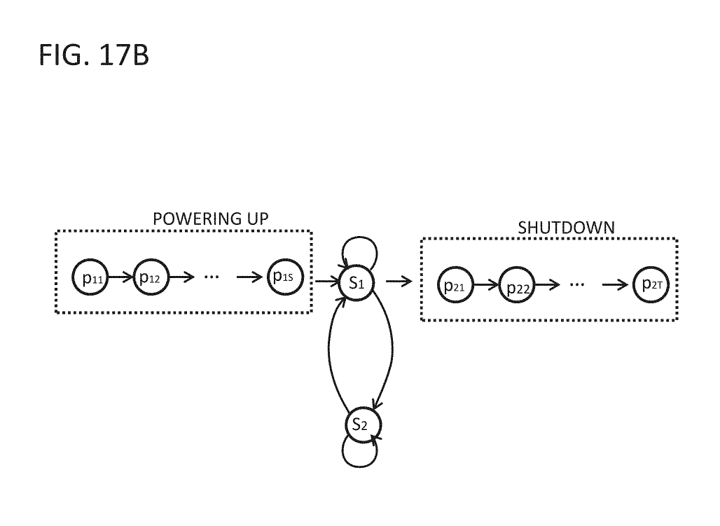

The following describes a third example embodiment of the invention. In the third example embodiment, a plurality of identical personal computers are connected to a distribution board, a printer or the like is additionally connected, and waveforms for individual devices are disaggregated in a case where a plurality of identical personal computers are connected. For example, a power supply current (a composite current waveform of electrical home appliances including personal computers 24A and 24B, and a printer 25 that are connected via a branch breaker to the distribution board 22) which is detected by a current sensor 23 that detects a current flowing in a main line (or branch breaker) of a distribution board 22 in FIG. 17A, or a current waveform or voltage waveform obtained by a smart meter 26 installed at a service entrance of a house 20, may be transmitted to a waveform disaggregation apparatus 10 via a communication apparatus 21 such as a HEMS (Home Energy Management System)/BEMS (Building Energy Management System) controller or the like. The waveform disaggregation apparatus 10 may perform estimation of current waveform and estimation of operation state of the personal computer.

An operation state of a personal computer after power up, generally depends on how a user uses the personal computer. Thus, imposing a fixed operational constraint may be almost impossible.

However, a transition of an operation state of a personal computer power supply ON (at powering up) operation or a power supply OFF (at shutting down), operation is basically in a one directional single path transition. For example, in a case where types (model, machine type, etc.) are identical, or where OSs (Operating Systems) are identical, or a case where applications that start up automatically after the OS starts up, or applications that operate automatically before shutdown are identical, a power-up sequence or a shutdown sequence for the personal computer in question are basically identical (excepting where start up does not happen due to some trouble). Alternatively, a model may be created by a model creation section (15 in FIG. 16) based on a result of monitoring a power supply current of a power-up sequence or shutdown sequence of the personal computer.

As illustrated in FIG. 17B, a constraint where an operation state of a unit is in a first state at a certain time, and is in a second state at time t+1 (the state transition has a one directional single path segment) is applied to a power-up sequence (for example, states p₁₁ to p_{1S}: S is an integer greater than or equal to 1) and a power-down sequence (for example state p₂₁ to p_{2T}: T is an integer greater than or equal to 1). After the power-up sequence, in state S₁, there occurs a transition to state S₂, responsive to an operation input (command input). In the state S₂, command processing is executed and after processing execution, there is a transition to state S₁. When the operation input is a shut down, there occurs a transition to a shutdown sequence. However, the state transition of a personal computer after powering up is simplified to a transition between states S₁ and S₂.

According to the third example embodiment, it is possible to extract a waveform of an individual personal computer on which a fixed operational constraint is imposed, from a composite current waveform of a plurality of identical personal computers, for example. As a result, it is possible to estimate an operation state (what time the power supply is turned ON or OFF, etc.) of the identical personal computers.

### Fourth Example Embodiment

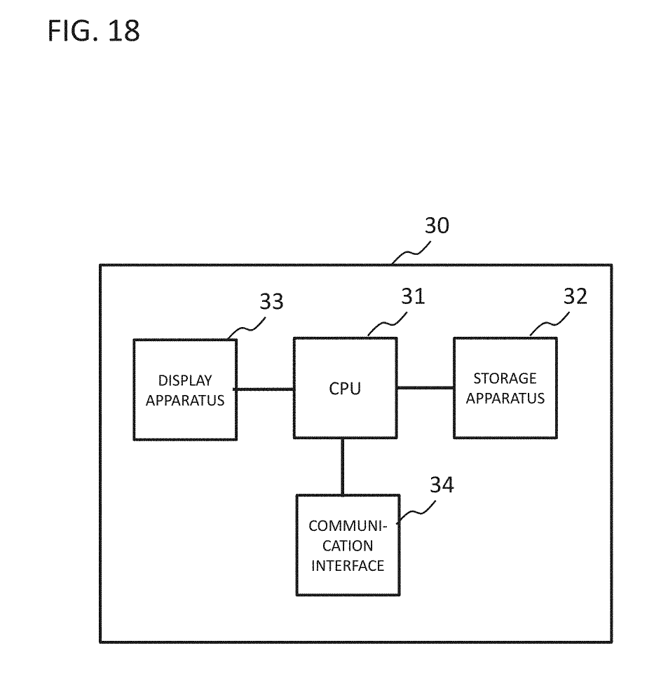

FIG. 18 is a diagram illustrating a fourth example embodiment of the invention. In the fourth example embodiment, a waveform disaggregation apparatus 10 of FIG. 1, FIG. 6 and FIG. 7 is illustrated by an example of a configuration implemented by a computer apparatus 30. Referring to FIG. 18, the computer apparatus 30 includes a CPU (Central Processing Unit) 31, a storage apparatus (memory) 32, a display apparatus 33 and a communication interface 34. The storage apparatus 32 may be, for example, semiconductor storage, such as RAM, ROM, EEPROM, or HDD, CD, DVD, or the like. The storage apparatus 32 stores a program executed by the CPU 31. The CPU 31 executes the program stored in the storage apparatus 32 to realize functions of the waveform disaggregation apparatus 10 of FIG. 1, FIG. 6 and FIG. 7. The communication interface 34 is connected for communication with a communication apparatus 101 of FIG. 6. Similarly, the CPU 31 may execute the program stored in the storage apparatus 32 to realize functions of the waveform disaggregation apparatus 10A of FIG. 16.

### <Computation Amount Reduction Effect>

As described above, in the above described respective example embodiments it is possible to disaggregate waveforms of a plurality of units with identical configuration by including a one directional single path segment in a model (state transition model) of an operation state of a unit. That is, it is possible to distinguish which unit corresponds to which waveform. In addition, computation amount (quantity) is reduced by including a one directional single path segment in the state transition model. A description is given below concerning this point.

In a forward algorithm and a backward algorithm used in state estimation, multiplication of a transition probability matrix and a probability vector is necessary. Since a transition probability matrix A is a sparse matrix (many elements of the matrix are 0), when calculating a product of the transition probability matrix A and the probability vector P, it is possible to greatly reduce computation amount by excluding zero elements from the computation in advance.

$$AP = {\sum }_{j = 1}^{M} {A}_{ij} {P}_{j} = {\sum }_{j : {A}_{ij} \neq 0} {A}_{ij} {P}_{j} \qquad ( 9 )$$

Similarly, in the Viterbi algorithm used in estimating a state, computation is necessary to obtain a maximum value in each column of a product of elements of the transition probability matrix and elements of the probability matrix. In this case also, by removing zero elements of the probability matrix from computation of the maximum value in advance, it is possible to greatly reduce computation amount.

$${max}_{j} \{ {A}_{ij} {P}_{j} \} = {max}_{j : {A}_{ij} \neq 0} \{ {A}_{ij} {P}_{j} \} \qquad ( 10 )$$

When a constraint as in FIG. 2B is imposed, this corresponds to narrowing down a selection in advance, by removing impossible state transitions.

When a probability that a value of a state variable Sₜ⁽¹⁾ of factor 1 is a state #i, and a value of a state variable Sₜ⁽²⁾ of factor 2 is state #j, is given at a certain time t,

α_{i,j}=P[Sₜ⁽¹⁾=i,Sₜ⁽²⁾=j] (11)

a probability that a value of a state variable Sₜ₊₁⁽¹⁾ of factor 1 at a next time t+1 is state #k, and a value of a state variable Sₜ₊₁⁽²⁾ of factor 2 is a state #1, is given by the following expression (12).

$$\begin{matrix}P [ {S}_{t + 1}^{( 1 )} = k , {S}_{t + 1}^{( 2 )} = I ] = {\sum }_{i , j} P [ {S}_{t + 1}^{( 1 )} = k , {S}_{t + 1}^{( 2 )} = I \vert {S}_{t}^{( 1 )} = i , {S}_{t}^{( 2 )} = j ] P [ {S}_{t}^{( 1 )} = i , {S}_{t}^{( 2 )} = j ] \\ = {\sum }_{i , j} {A}_{i , k} {B}_{j , i} {α}_{i , j} \\ = ( A ⊗ B ) α\end{matrix} \qquad ( 12 )$$

Here, the Kronecker product

A⊗B

with A=(aᵢⱼ) being an m×n matrix, B=(bₖ₁) being a p×q matrix, is a mp×nq partition segmented matrix.

$$A ⊗ B = ( \begin{matrix}{a}_{11} B & … & {a}_{1 n} B \\ ⋮ & ⋱ & ⋮ \\ {a}_{m 1} B & … & {a}_{mn} B\end{matrix} ) \qquad ( 13 )$$

For example, for the transition probability matrix A (3×3) of FIG. 2B, and the transition probability matrix B(3×3) of FIG. 2C (states #1, #2, #3), the following is given.

$${( A ⊗ B )}_{i , j ; k , l} = [ \begin{matrix}{a}_{11} {b}_{11} & {a}_{11} {b}_{12} & {a}_{11} {b}_{13} & {a}_{12} {b}_{11} & {a}_{12} {b}_{12} & {a}_{12} {b}_{13} & {a}_{13} {b}_{11} & {a}_{13} {b}_{12} & {a}_{13} {b}_{13} \\ {a}_{11} {b}_{21} & {a}_{11} {b}_{22} & {a}_{11} {b}_{23} & {a}_{12} {b}_{21} & {a}_{12} {b}_{22} & {a}_{12} {b}_{23} & {a}_{13} {b}_{21} & {a}_{13} {b}_{22} & {a}_{13} {b}_{23} \\ {a}_{11} {b}_{31} & {a}_{11} {b}_{32} & {a}_{11} {b}_{33} & {a}_{12} {b}_{31} & {a}_{12} {b}_{32} & {a}_{12} {b}_{33} & {a}_{13} {b}_{31} & {a}_{13} {b}_{32} & {a}_{13} {b}_{33} \\ 0 & 0 & 0 & 0 & 0 & 0 & {b}_{11} & {b}_{12} & {b}_{13} \\ 0 & 0 & 0 & 0 & 0 & 0 & {b}_{21} & {b}_{22} & {b}_{23} \\ 0 & 0 & 0 & 0 & 0 & 0 & {b}_{31} & {b}_{32} & {b}_{33} \\ {a}_{31} {b}_{11} & {a}_{31} {b}_{12} & {a}_{31} {b}_{13} & 0 & 0 & 0 & {a}_{33} {b}_{11} & {a}_{33} {b}_{12} & {a}_{33} {b}_{13} \\ {a}_{31} {b}_{21} & {a}_{31} {b}_{22} & {a}_{31} {b}_{23} & 0 & 0 & 0 & {a}_{33} {b}_{21} & {a}_{33} {b}_{22} & {a}_{33} {b}_{23} \\ {a}_{31} {b}_{31} & {a}_{31} {b}_{32} & {a}_{31} {b}_{33} & 0 & 0 & 0 & {a}_{33} {b}_{31} & {a}_{33} {b}_{32} & {a}_{33} {b}_{33}\end{matrix} ] \qquad ( 14 )$$

In the above matrix, there are 54 non-zero elements among 9×9=81 matrix elements. In computation of a product of this matrix and a vector product in a forward algorithm or a backward algorithm, or computation of a maximum value appearing in a Viterbi algorithm, it is possible to reduce computation amount by skipping calculation of zero elements. When the number of operation constraints according to the present example embodiment increase, non-zero elements become fewer and computation time is shortened.

Next a description is given concerning computation amount in iterations of E step in Structured Variational Inference according to the present example embodiment.

A computation amount for a product of a matrix and a vector is proportional to the number of non-zero elements in the matrix (the above expression 9). In a normal Factorial HMM with a non-sparse matrix, there are M\hat{ }2 non-zero elements for M states in a transition probability matrix (\hat{ } is exponential operator).

In the present example embodiment, as illustrated in the example of FIG. 9, where there are T+1 states of w, p₁, . . . , and p_{T}, there are T+2 state transitions, w→p₁, p1→p₂, . . . , p_{T-1}→p_{T}, p_{T}→w, and w→w, so that the computational amount is of an order of T to the power of 1 (not 2). E step in Structured Variational Inference disclosed in Non-Patent Literature 1 is an iterative solution technique, and in each interaction a forward-backward algorithm is executed. In this case, a product of a transition probability matrix and a probability vector is performed KN times. Therefore, the computational amount is of an order O(KNT).

### <Analysis of Related Technology (Patent Literature 2)>

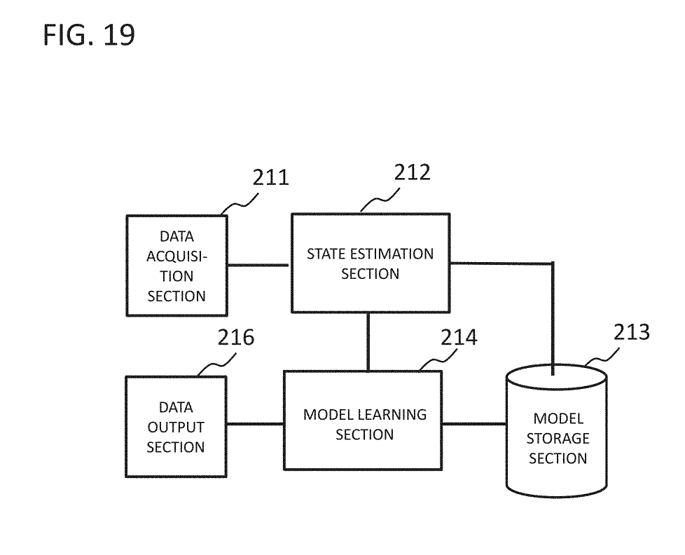

Next, with related technology (Patent Literature 2) described with reference to FIG. 19, it is impossible to obtain a constraint-imposed model, by chance, as a result of learning. The reason is as follows.

In the related technology (Patent Literature 2), in order that elements of a transition probability matrix be zero by chance, as a result of learning, in M step, in an updating expression of a state transition probability matrix Aᵢ, j^{(m)} (in expression (15) of Patent Literature 2, A_{i,j}^{(m)new} is p_{i,j}^{(m)new}).

$${A}_{i , j}^{( m ) new} = \frac{{\sum }_{t = 2}^{T} 〈 {S}_{t - 1 , i}^{( m )} {S}_{t , j}^{( m )} 〉}{{\sum }_{t = 2}^{T} 〈 {S}_{t - 1 , i}^{( m )} 〉} \qquad ( 15 )$$

a right side must be zero.

<S_{t-1,i}^{(m)}, S_{t,j}^{(m)}> is an element of i-th row and j-th column of the K×K posterior probability <Sₜ₋₁^{(m)}Sₜ^{(m)}>, and represents a state probability of a state being in state #j at a next time t, when the state is in state #i at time t−1. <S_{t-1,i}^{(m)}> represents a state probability of a state being in state #i at time t−1.

In M step, a model learning section 214 of FIG. 19 obtains an update value W^{(m)new} of a characteristic waveform W^{(m)} by performing waveform disaggregation learning using a measured waveform Yₜ and posterior probabilities <Sₜ^{(m)}> and <Sₜ^{(m)}Sₜ^{(n′)}>. Next, the model learning section 214 obtains an update value of distribution C, using the measured waveform Yₜ, the posterior probability <Sₜ^{(m)}>, and the characteristic waveform (update value) W^{(m)}. Next, the model learning section 214 obtains an update value A_{i,j}^{(m)new} of the above transition probability and an update valueπ^{(m)new} of an initial state probability π^{(m)}, using the posterior probabilities <Sₜ^{(m)}> and <Sₜ₋₁^{(m)}Sₜ^{(m)′}>.

In order that a numerator of the right side of the above expression (15) is zero, for posterior probabilities <Sₜ₋₁^{(m)} Sₜ^{(m)′}> (expression (11) of Patent Literature 2),

$$〈 {S}_{t - 1}^{( m )} {S}_{t}^{{( m )}^{′}} 〉 = \frac{{\sum }_{w ∈ {S}_{t - 1}^{( n )} , z ∈ {S}_{t}^{( r )} ( n \neq m ⋀ r \neq m )} {α}_{t - 1 , w} P ( z \vert x ) P ( {Y}_{t} \vert z ) {β}_{t , z}}{{\sum }_{w ∈ {S}_{t - 1} , z ∈ {S}_{t}} {α}_{t - 1 , w} P ( z \vert x ) P ( {Y}_{t} \vert z ) {β}_{t , z}} \qquad ( 16 )$$

a sum of numerators on the right side must all be zero. It is noted that P(z|w) is a probability of a transition to a combination z of states from a combination w of states. This is obtained as a product of as from P⁽¹⁾_{i(1),j(1)} which is a transition probability from a state #i(1) of factor #1 configuring a combination w of states to a state #j(1) of factor #1 configuring a combination z of states, to P^{(M)}_{i(M),i(M)} which is a transition probability from a state #i(M) of factor #M configuring a combination w of states to a state #j(M) of factor #M configuring a combination z of states. The transition probability P(Sₜ|Sₜ₋₁) is given by the following expression (17).

$$P ( {S}_{t} \vert {S}_{t - 1} ) = {\prod }_{m = 1}^{M} P ( {S}_{t}^{( m )} \vert {S}_{t - 1}^{( m )} ) \qquad ( 17 )$$

With respect to factor m, P(Sₜ^{(m)}|Sₜ₋₁^{(m)}) is a probability of transitioning to state Sₜ^{(m)} at time t, when being in state Sₜ₋₁^{(m)} at time t−1.

An observed probability P(Yₜ|Sₜ) is given by the following (expression (4) of Patent Literature 2).

P(Yₜ|Sₜ)=|C|^{-1/2}(2π)^{-D/2} exp {−½(Yₜ−μₜ)C⁻¹(Yₜ−μₜ)} (18)

A dash (′) represents a transpose. From the above expression, P(Yₜ|z)>0.

Since a forward probability α_{t-1,w} of Factorial HMM and backward probability β_{t, z} of Factorial HMM are probability variables, a certain w and z exist, and

α_{t-1,w}>0, β_{t,z}>0. (19)

Therefore, in order that “elements of a transition probability matrix after update are zero”, “elements of the transition probability matrix before update are zero”.

That is, as long as elements of the transition probability matrix are not made to zero before learning, they are not zero after learning. From the above, it has been shown that a constraint introduced in an example embodiment of the present invention is not something that can be automatically learned by a known learning algorithm such as an EM algorithm or the like.

### Fifth Example Embodiment

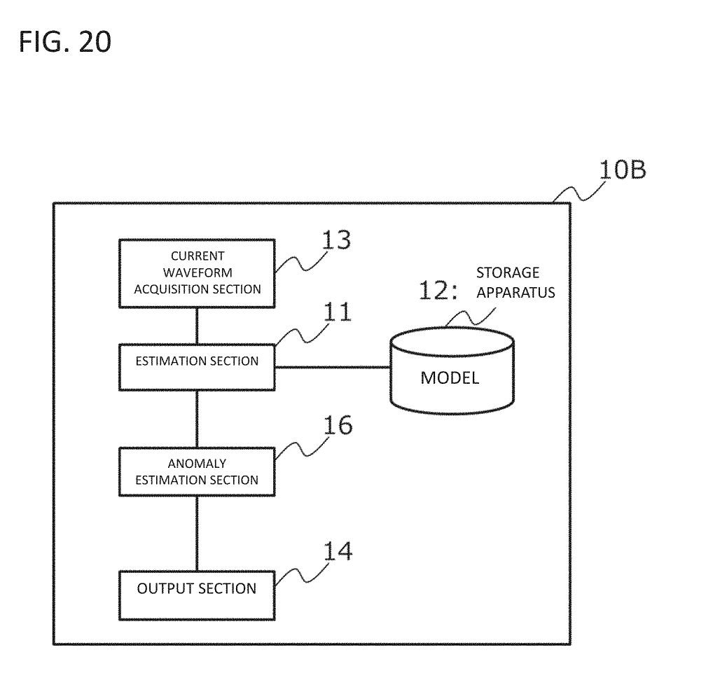

Next, a description is given regarding a fifth example embodiment of the invention, with reference to FIG. 20. Referring to FIG. 20, a waveform disaggregation apparatus 10B in the fifth example embodiment differs from waveform disaggregation apparatuses 10 and 10A of the first and second example embodiments in being provided with an anomaly estimation section 16. It is noted that identical reference symbols are attached to configurations having identical functions as configurations described in the first and second example embodiments, and descriptions thereof are omitted.

The anomaly estimation section 16 of the waveform disaggregation apparatus 10B of the fifth example embodiment receives a signal waveform disaggregated by the estimation section 11 that estimates and disaggregates signal waveforms of a plurality of individual units, based on a state transition model, from a composite signal waveform, and detects an anomaly in a unit from the disaggregated signal waveform or a prescribed state. The state transition model, as a model of operation states of a unit, may preferably have a configuration including a first state transition model having a segment for transition along one directional single path.

In related technology, in a case of performing anomaly monitoring of a system using a waveform of electrical current or the like, when the system includes a plurality of units, it is not easy to detect in which unit an anomaly occurs.

The reason for this is as follows. When performing anomaly monitoring using signal waveforms of individual units, a large number of sensors are required for each individual unit, and as a result, cost increases (rises). Instead of installing sensors in individual units, in a case of performing anomaly monitoring using an entire waveform (composite signal waveform) of a system including a plurality of units, it may be possible to detect an occurrence of an anomaly from the entire waveform of the system, but it may not be easy to detect in which unit the anomaly occurs.

According to the fifth example embodiment, in a system including a plurality of units, by performing waveform disaggregation of an entire waveform (composite signal waveform of a plurality of units) of the system measured by a small number of sensors, with high accuracy, for each unit, it is possible to detect in which unit an anomaly occurs.

For example, regarding a plurality of units of identical or nearly identical configuration, even when accuracy in disaggregation accuracy in which a composite waveform is disaggregated into waveforms of the individual units in related technology, it is possible to detect a unit in which an anomaly occurs with good accuracy, according to the fifth example embodiment.

While there is no particular limitation, for example, in a case of a facility where a plurality of units configure a production line, by monitoring for “a situation (anomaly) which is different from normal”, it is possible to detect and cope with a failure of the facility or quality anomaly of products at an early stage, as a result of which it is possible to reduce production stoppage time (down time) and to improve production yield.

As another example, in a case where a plurality of units includes personal computers, by monitoring for a situation which is different from normal, it is possible to detect and cope with, at an early stage, contamination by malware (unauthorized software) in a personal computer, for example. As a result, it is possible to reduce risks with regard to information security.

In a case of the above described examples, situations often occur where a plurality of units (production facilities, personal computers, or the like) have identical or nearly identical configurations. In such a case, it is not easy to detect in which unit and in which operation an anomaly occurs, only with simple monitoring for a situation which is different from normal.

According to the fifth example embodiment, for example, even in a case where there are a plurality of units of identical or nearly identical configurations, it is possible to detect in which unit and in which operation an anomaly occurs.

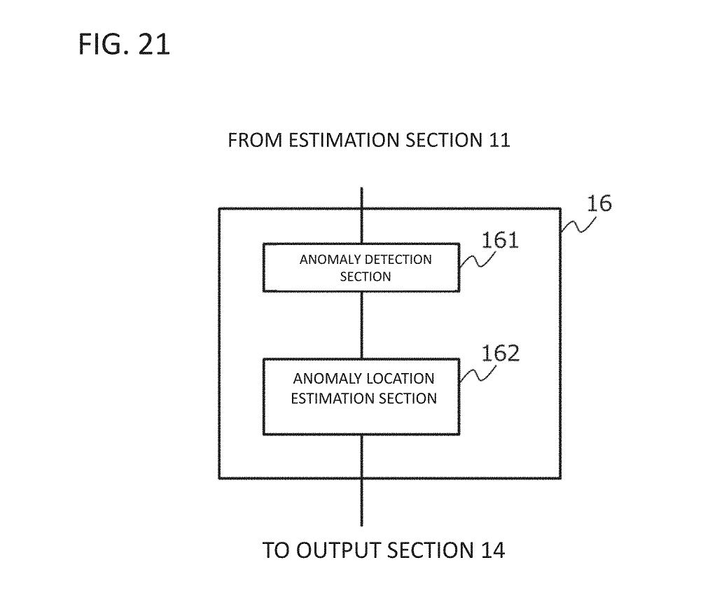

FIG. 21 is a diagram illustrating an anomaly estimation section 16 in the fifth example embodiment. The anomaly estimation section 16 includes an anomaly detection section 161 and an anomaly location estimation section 162.

The anomaly detection section 161 calculates anomaly level indicating an occurrence degree of anomaly for a waveform disaggregated for each unit, based on a disaggregating result of a signal waveform by an estimation section 11, and by comparing the anomaly level with a predetermined threshold, for example, decides whether or not there is an anomaly.

In the anomaly detection section 161, as an example of anomaly level, for example, KL divergence at each point of time may be used. KL divergence at each point of time corresponds to an extraction of contribution at time tin expression (4), and may be obtained by the following expression.

$${KL}_{t} = {\sum }_{m = 1}^{M} 〈 {S}_{t}^{( m )} 〉 log {h}_{t}^{( m )} + \frac{1}{2} [ {Y}_{t}^{′} {C}^{- 1} {Y}_{t} + {\sum }_{m = 1}^{M} {\sum }_{n \neq m}^{M} tr \{ {W}^{{( m )}^{′}} {C}^{- 1} {W}^{( n )} 〈 {S}_{t}^{( n )} 〉 〈 {S}_{y}^{{( m )}^{′}} 〉 \} + {\sum }_{m = 1}^{M} tr \{ {W}^{{( m )}^{′}} {C}^{- 1} {W}^{( m )} diag \{ 〈 {S}_{t}^{( m )} 〉 \} \} ] \qquad ( 20 )$$

Here, as for values of variables <Sₜ^{(m)}> and hₜ^{(m)}, values are used that have been estimated, for example, by the estimation section 11, as described in the first and second example embodiment. In this case, the KL divergence at each point of time indicates a measure of difference between model distribution and measured value Yₜ, and it may be considered that the more an anomaly is included in the measured value, the greater a value of KL divergence.

Therefore, in the anomaly detection section 161, it is possible to detect an occurrence of an anomaly according to whether or not a value KLₜ of KL divergence at each point of time is greater than a predetermined threshold (first threshold). That is, the anomaly detection section 161 decides that an anomaly occurs in a case where KLₜ is greater than the first threshold.

As another example of anomaly level, for example, a marginal likelihood at each point of time may be used. A marginal likelihood at each point of time is a probability density where a measured value Yₜ at time t is obtained from a model. A marginal likelihood Lₜ at each point of time is obtained by the following expression (21) by using residual ^{˜}Yₜ^{(m)} obtained according to the expression (6b), for example.

$${L}_{t} = \frac{1}{\sqrt{det ( 2 π C )}} exp \{ - \frac{1}{2} {\tilde{Y}}_{t}^{{( m )}^{′}} {C}^{- 1} {\tilde{Y}}_{t}^{( m )} \} \qquad ( 21 )$$

In this case, it is considered that the more an anomaly is included in a measured value Yₜ, the smaller the value of marginal likelihood Lₜ at each point of time. Therefore, in the anomaly detection section 161, it is possible to detect an occurrence of an anomaly according to whether or not the marginal likelihood Lₜ at each point of time is smaller than a predetermined threshold (second threshold). That is, the anomaly detection section 161 decides that an anomaly occurs when Lₜ is smaller than the second threshold.

Next, an estimation is made as to in which unit (factor) an anomaly occurs, by the anomaly location estimation section 162 of the anomaly estimation section 16.

When an anomaly is detected at time t by the anomaly detection section 161, each factor m is in a state Sₜ^{(m)}. Therefore, in the anomaly location estimation section 162, by estimating a pair (m, Sₜ^{(m)}) of the state Sₜ^{(m)} corresponding to a factor m in which an anomaly occurs, it is possible to estimate in which unit an anomaly occurs, and in which operation of the unit the anomaly occurs.

Here, as an estimated value of a state Sₜ^{(m)} corresponding to each factor m, it is possible to use, for example, a value of the expression (7) which is used in the estimation section 11.

By so doing, the anomaly location estimation section 162 can obtain M items of candidates, that is, candidates of pairs (m, Sₜ^{(m)}), where m=1, . . . , M, for a factor m and a state Sₜ^{(m)} in which an anomaly occurs.

Next, in the anomaly location estimation section 162, among M candidates of set (m, Sₜ^{(m)}) of factor and state in which an anomaly occurs, a priority is assigned according to a value of state Sₜ^{(m)}.

The anomaly location estimation section 162 outputs the set (m, Sₜ^{(m)}) of a factor and state that have higher priority assigned.

It is noted that in the anomaly location estimation section 162 may adopt a criterion(s) with which the priority is determined, one or a plurality of combinations of criterions below may be used (but not limited thereto).

(a) State Sₜ^{(m)} is an internal part of a fixed constraint segment in the model 123 (FIG. 7).
(b) Norm of weighting vector Wⱼ^{(m)} corresponding to state Sₜ^{(m)}=j has a larger value.
(c) State Sₜ^{(m)} is a state when a specific time Δt has elapsed from a start point of a segment of the fixed operation constraint, in an internal part of the fixed operation constraint segment in the model 123 (FIG. 7).

Here, criterion (a) means that unit m is in the middle of performing repeated operations. Therefore, in the anomaly location estimation section 162, by using criterion (a), and by reflecting a general situation that “an anomaly occurs more easily in a unit in operation than in a unit that is stopped”, it is possible to correctly estimate a factor in which an anomaly occurs.

Criteria (b) means that a dimension of waveform (for example, amplitude or root mean square value of the waveform) disaggregated by the estimation section 11 is larger in unit m. For example, in a case where an input signal to the waveform disaggregation apparatus 10B is power, acoustic signal, oscillation, communication amount or the like, in general a larger signal is generated for a unit in operation in comparison with a unit that is stopped. Therefore, in the anomaly location estimation section 162, by using criterion (b), and by reflecting the situation that “an anomaly occurs more easily in a unit in operation than in a unit that is stopped”, it is possible to correctly estimate a factor in which an anomaly occurs.

Criteria (c) means that unit m which is in the middle of repeated operations, performs a specific operation. Therefore, in the anomaly location estimation section 162, by using criterion (c) and by reflecting a situation that “an anomaly occurs more easily in a unit that is in the middle of performing a specific operation than in a unit that is not in the middle of performing a specific operation”, it is possible to correctly estimate a factor in which an anomaly occurs.

In the above described example, the anomaly location estimation section 162, regarding a set of (m, Sₜ^{(m)}) of a factor and state in which an anomaly occurs, outputs plural sets with higher priority. The anomaly location estimation section 162 may output, as another output form,
a single set with highest priority may be outputted, or
a plurality of sets may be outputted in order of priority, or
numerical values representing priority may be output in association with respective sets.

In the above described example, the anomaly location estimation section 162, determines, as a candidate of set (m, Sₜ^{(m)}) of a factor and state in which an anomaly occurs, only one state Sₜ^{(m)} corresponding to each factor m using the expression (7), but it is possible to use a plurality of values, as state Sₜ^{(m)} corresponding to each factor m.

In this case, since the probability that the state of factor m is Sₜ^{(m)}=j is <S_{t,j}^{(m)}>, when determining a priority of a set (m, Sₜ^{(m)}) of a factor and state in which an anomaly occurs, the anomaly location estimation section 162 may set a new criterion:

(d) a probability <Sₜ^{(m)}=j> corresponding to state Sₜ^{(m)}=j has a larger value. With combination of criterion (d) with the above criterion (a)-(c), the priority may be determined. In this way, for example, even in a case where a state occurs in which accuracy of waveform disaggregation deteriorates in the estimation section 11, and one state for each factor is not determined, the anomaly location estimation section 162 can output potential candidates for anomaly occurrence location.

In the fifth example embodiment, operation of the waveform disaggregation apparatus 10B may sequentially be executed (online processing) each time a waveform is obtained by the current waveform acquisition section 13. Alternatively, operation of the waveform disaggregation apparatus 10B may be executed collectively (batch processing) after a plurality of waveforms obtained by the current waveform acquisition section 13 are stored.

Here, in a case where it is necessary to shorten time from occurrence of anomaly to detection thereof, it is desirable to execute online processing to reduce holding time of a waveform. On the other hand, in a case where accuracy rather than speed of anomaly estimation is required, it is desirable to perform batch processing.

As described above, according to the fifth example embodiment, it is possible not only to perform disaggregation of a waveform of a unit, but also to detect an anomaly that occurs in a unit, and to estimate a unit in which an anomaly occurs.

It is noted that the respective disclosures of the above described Patent Literature 1-6 and Non-Patent Literature 1 and 2 are incorporated herein by reference thereto. Modifications and adjustments of example embodiments and examples may be made within the bounds of the entire disclosure (including the scope of the claims) of the present invention, and also based on fundamental technological concepts thereof. Furthermore, various combinations and selections of various disclosed elements (including respective elements of the respective appendices, respective elements of the respective example embodiments, respective elements of the respective drawings, and the like) are possible within the scope of the claims of the present invention. That is, the present invention clearly includes every type of transformation and modification that a person skilled in the art can realize according to the entire disclosure including the scope of the claims and to technological concepts thereof.

The above described example embodiments may also be described as follows (but not limited thereto).

### (Supplementary Note 1)

A waveform disaggregation apparatus comprising:

a storage apparatus that stores, as a model of an operation state of a unit, a first state transition model including a segment in which each state transition occurs along a one directional single path; and

an estimation section that receives a composite signal waveform of a plurality of units including a first unit that operates based on the first state transition model,

the estimation section performing, at least based on the first state transition model, estimation of a signal waveform of the first unit from the composite signal waveform to separate the signal waveform therefrom.

### (Supplementary Note 2)

The waveform disaggregation apparatus according to supplementary note 1, wherein the plurality of units include a second unit, identical to or a type thereof being identical to, the first unit, wherein the estimation section disaggregates, from a composite signal waveform of the first unit and the second unit, a signal waveform of the first unit and a signal waveform of the second unit, based on the first state transition model corresponding to the first unit and a state transition model of the second unit.

### (Supplementary Note 3)

The waveform disaggregation apparatus according to supplementary note 1 or 2, wherein the first unit operating under a constraint corresponding to the segment of the first state transition model, when in a first state at a certain time, transitions, at a subsequent time, to a second state with transition probability of 1.

### (Supplementary Note 4)

The waveform disaggregation apparatus according to supplementary note 2, wherein the first units the and second units comprise any out of:

first and second units within one facility, the facility configuring one production line;

first and second facilities, each configuring one production line;

a first unit of a first facility configuring a first production line, and a second unit of a second facility configuring a second production line; and

first and second home electrical appliances.

### (Supplementary Note 5)

The waveform disaggregation apparatus according to any one of supplementary notes 1-4, comprising

a current waveform acquisition section that obtains a composite current waveform of the plurality of units, as the composite signal waveform.

### (Supplementary Note 6)

The waveform disaggregation apparatus according to any one of supplementary notes 1-5, further including

a model creation section that creates a model of an operation state of the unit to store the model in the storage apparatus.

### (Supplementary Note 7)

The waveform disaggregation apparatus according to any one of supplementary notes 1-6, wherein one state before or one state after is estimated, based on the first state transition model and a prescribed state.

### (Supplementary Note 8)

The waveform disaggregation apparatus according to any one of supplementary notes 1-6, wherein the estimation section estimates a prescribed state, based on the first state transition model and a state at a preceding time or at a succeeding time.

### (Supplementary Note 9)

The waveform disaggregation apparatus according to any one of supplementary notes 1-8, wherein a model of an operation state of the unit corresponds to a factor of a Factorial Hidden Markov Model (FHMM).

### (Supplementary Note 10)

A computer-based waveform disaggregation method comprising:

regarding a composite signal waveform of a plurality of units including a first unit that operates based on a first state transition model, the first state transition model including a segment in which each state transition in occurs along a one directional single path,

performing, based on the first state transition model, estimation of a signal waveform of the first unit from the composite signal waveform to separate the signal waveform therefrom.

### (Supplementary Note 11)

The waveform disaggregation method according to supplementary note 10, wherein the plurality of units include a second unit, identical to or a type thereof being identical to, the first unit, wherein the method comprises

disaggregating a composite signal waveform of the first unit and the second unit into a signal waveform of the first unit and a signal waveform of the second unit, based on the first state transition model corresponding to the first unit and a state transition model of the second unit.

### (Supplementary Note 12)

The waveform disaggregation method according to supplementary note 10 or 11, wherein the first unit operating under a constraint corresponding to the segment of the first state transition model, when in a first state at a certain time, transitions, at a subsequent time, to a second state with transition probability of 1.

### (Supplementary Note 13)

The waveform disaggregation method according to supplementary note 11, wherein the first units the and second units include any out of:

first and second units within one facility, the facility configuring one production line;

first and second facilities, each configuring one production line;

a first unit of a first facility configuring a first production line, and a second unit of a second facility configuring a second production line; and

first and second home electrical appliances.

### (Supplementary Note 14)

The waveform disaggregation method according to any one of supplementary notes 10-13, comprising

a current waveform acquisition step that obtains a composite current waveform of the plurality of units, as the composite signal waveform.

### (Supplementary Note 15)

The waveform disaggregation method according to any one of supplementary notes 10-15, further comprising

a model creation step that creates a model of an operation state of the unit.

### (Supplementary Note 16)

The waveform disaggregation method according to any one of supplementary notes 10-15, comprising

estimating a state at a preceding time or at a succeeding time, based on the first state transition model and a prescribed state.

### (Supplementary Note 17)

The waveform disaggregation method according to any one of supplementary notes 10-15, comprising

estimating a prescribed state, based on the first state transition model and a state at a preceding time or at a succeeding time.

### (Supplementary Note 18)

The waveform disaggregation method according to any one of supplementary notes 10-15, wherein a model of an operation state of the unit corresponds to a factor of a Factorial Hidden Markov Model (FHMM).

### (Supplementary Note 19)

A program causing a computer to execute processing comprising:

receiving a composite signal waveform of a plurality of units including a first unit that operates based on a first state transition model, the first state transition model including a segment in which each state transition in occurs along a one directional single path; and

performing, based on the first state transition model, estimation of a signal waveform of the first unit from the composite signal waveform to separate the signal waveform therefrom.

### (Supplementary Note 20)

The program according to supplementary note 19, wherein the plurality of units include a second unit, identical to or a type thereof being identical to, the first unit, wherein the estimating processing comprises

disaggregating a composite signal waveform of the first unit and the second unit into a signal waveform of the first unit and a signal waveform of the second unit, based on the first state transition model corresponding to the first unit and a state transition model of the second unit.

### (Supplementary Note 21)

### (Supplementary Note 21)

The program according to supplementary note 19 or 20, wherein the first unit operating under a constraint corresponding to the segment of the first state transition model, when in a first state at a certain time, transitions, at a subsequent time, to a second state with transition probability of 1.

### (Supplementary Note 22)

The program according to supplementary note 11, wherein the first units the and second units include any out of:

first and second units within one facility, the facility configuring one production line;

first and second facilities, each configuring one production line;

a first unit of a first facility configuring a first production line, and a second unit of a second facility configuring a second production line; and

first and second home electrical appliances.

### (Supplementary Note 23)

The program according to any one of supplementary notes 19-22, comprising a current waveform acquisition processing that obtains a composite current waveform of the plurality of units, as the composite signal waveform.

### (Supplementary Note 24)

The program according to any one of supplementary notes 19-23, comprising a current waveform acquisition processing that obtains a composite current waveform of the plurality of units, as the composite signal waveform.

### (Supplementary Note 25)

The program according to any one of supplementary notes 19-24, comprising

estimating a prescribed state, based on the first state transition model and a state at a preceding time or at a succeeding time.

### (Supplementary Note 26)

The program according to any one of supplementary notes 19-24, comprising estimating a prescribed state from the first state transition model, and one state before or one state after.

### (Supplementary Note 27)

The program according to any one of supplementary notes 19-24, wherein a model of an operation state of the unit corresponds to a factor of a Factorial Hidden Markov Model (FHMM).

### (Supplementary Note 28)

The waveform disaggregation apparatus according to any one of supplementary notes 1-9, further comprising

an anomaly estimation section that detects an anomaly of the unit, from the signal waveform disaggregated by the estimation section or a prescribed state.

### (Supplementary Note 29)

The waveform disaggregation apparatus according to supplementary note 28, wherein the anomaly estimation section calculates anomaly level indicating an occurrence degree of anomaly, based on the signal waveform disaggregated by the estimation section or a prescribed state and compares the anomaly level with a threshold to decide whether or not an anomaly occurs.

### (Supplementary Note 30)

The waveform disaggregation apparatus according to supplementary note 28 or 29, wherein the anomaly estimation section estimates either one or both of a factor in which an anomaly occurs or a state in which an anomaly occurs, based on the signal waveform disaggregated by the estimation section or a prescribed state and compares the anomaly level with a threshold to decide whether or not anomaly occurs.

### (Supplementary Note 31)

The waveform disaggregation apparatus according to supplementary note 30, wherein the anomaly estimation section determines priority for a set of the factor and the state, in accordance with an estimated value of a state corresponding to a time at which the anomaly is detected, and

estimates a set of the factor and the state with the priority being high, as either one or both of a factor in which the anomaly occurs and a state in which an anomaly occurs.

### (Supplementary Note 32)

The waveform disaggregation apparatus according to supplementary note 31, wherein the anomaly estimation section adopts as criterion for determining the priority, at least one of the followings:

(a) the state is included in the segment,

(b) a norm of a weight vector of the factorial hidden Markov model corresponding to the state has a large value,

(c) the state is a state where a specific time has elapsed from the start of the segment, and

(d) the state has a large occurrence probability value.

### (Supplementary Note 33)

The waveform disaggregation method according to any one of supplementary notes 10-18, comprising an anomaly estimating step of detecting an anomaly of the unit, from the disaggregated signal waveform or a prescribed state.

### (Supplementary Note 34)

The waveform disaggregation method according to any one of supplementary notes 33, wherein the anomaly estimating step calculates anomaly level indicating an occurrence degree of anomaly, from the disaggregated signal waveform or the prescribed state, and decides whether or not an anomaly occurs by comparing the anomaly level with a threshold.

### (Supplementary Note 35)

The waveform disaggregation method according to any one of supplementary notes 33 or 34, wherein the anomaly estimating step estimates either one or both of a factor in which an anomaly occurs or a state in which an anomaly occurs, based on the signal waveform disaggregated by the estimation section or a prescribed state and compares the anomaly level with a threshold to decide whether or not anomaly occurs.

### (Supplementary Note 36)

The waveform disaggregation method according to supplementary note 35, wherein the anomaly estimating step determines priority for a set of the factor and the state, in accordance with an estimated value of a state corresponding to a time at which the anomaly is detected, and

estimates a set of the factor and the state with the priority being high, as either one or both of a factor in which the anomaly occurs and a state in which an anomaly occurs.

### (Supplementary Note 37)

The waveform disaggregation method according to supplementary note 36, wherein the anomaly estimating step adopts as criterion for determining the priority, at least one of the followings:

(a) the state is included in the segment,

(b) a norm of a weight vector of the factorial hidden Markov model corresponding to the state has a large value,

(c) the state is a state where a specific time has elapsed from the start of the segment, and

(d) the state has a large occurrence probability value.

### (Supplementary Note 38)

The program according to supplementary note 19, causing the computer to execute an anomaly estimating step of detecting an anomaly of the unit, from the disaggregated signal waveform or a prescribed state.

### (Supplementary Note 39)

The program according to supplementary note 38, wherein the anomaly estimating processing calculates anomaly level indicating an occurrence degree of anomaly, from the disaggregated signal waveform or the prescribed state, and decides whether or not an anomaly occurs by comparing the anomaly level with a threshold.

### (Supplementary Note 40)

The program according to supplementary note 38 or 39, wherein the anomaly estimating processing estimates either one or both of a factor in which an anomaly occurs or a state in which an anomaly occurs, based on the signal waveform disaggregated by the estimation section or a prescribed state and compares the anomaly level with a threshold to decide whether or not anomaly occurs.

### (Supplementary Note 41)

The program according to supplementary note 40, wherein the anomaly estimating processing determines priority for a set of the factor and the state, in accordance with an estimated value of a state corresponding to a time at which the anomaly is detected, and

estimates a set of the factor and the state with the priority being high, as either one or both of a factor in which the anomaly occurs and a state in which an anomaly occurs.

### (Supplementary Note 42)

The program according to supplementary note 41, wherein the anomaly estimation processing adopts as criterion for determining the priority, at least one of the followings:

(a) the state is included in the segment,

(b) a norm of a weight vector of the factorial hidden Markov model corresponding to the state has a large value,

(c) the state is a state where a specific time has elapsed from the start of the segment, and

(d) the state has a large occurrence probability value.

### REFERENCE SIGNS LIST

1-1 to 1-3 waveform
2B-1 state transition diagram of factor 1
2B-2 transition probability matrix
2C-1 state transition diagram of factor 2
2C-2 transition probability matrix
3-1 to 3-5 composite waveform
4-1 to 4-5 composite waveform
5-1 state transition diagram of first half unit (stage 1)
5-2 state transition diagram of latter half unit (stage 2)
6A composite current waveform
6B current waveform of first unit
6C current waveform of latter unit
7A composite current waveform
7B to 7C current waveform of 3 factors
8A schematic diagram
8B schematic diagram
10, 10A, 10B waveform disaggregation apparatus
11 estimation section
12 storage apparatus
13 current waveform acquisition section
14 output section
15 model creation section
16 anomaly estimation section
20 building
21 communication apparatus
22 distribution board
23 current sensor
24A, 24B personal computer (PC)
25 printer
26 smart meter
30 computer apparatus
31 CPU
32 storage apparatus
33 display apparatus
34 communication interface
100 power supply (commercial AC supply)
101 communication apparatus
102 current sensor
103 distribution board
104 transformer
105 loader
106 solder printer
107 inspection machine 1
108 mounter
108A mounter 1
108B mounter 2
108C mounter 3
109 reflow oven
110 inspection machine 2
111 unloader
121-126 model (state transition model)
161 anomaly detection section
162 anomaly location estimation section
211 data acquisition section
212 state estimation section
213 model storage section
214 model learning section
216 data output section
1081A-1081D feeder
1082A, 1082B head
1083 conveyor
1084A, 1084B substrate

What is claimed is:

1. A waveform disaggregation apparatus comprising:
a processor;
a memory storing program instructions executable by the processor; and
a storage apparatus that stores, as a model of an operation state of a unit, a first state transition model including a segment in which each state transition occurs along a one directional single path,
wherein the processor is configured to
receive a composite signal waveform of respective signals of a plurality of units including a first unit that operates based on the first state transition model; and
perform, at least based on the first state transition model stored in the storage apparatus, estimation of a first signal waveform of the first unit from the composite signal waveform to separate the first signal waveform therefrom.

2. The waveform disaggregation apparatus according to claim 1, wherein the plurality of units include a second unit, identical to or a type thereof being identical to, the first unit,
wherein the processor is configured to disaggregate a composite signal waveform of signals of the first and second units into the first signal waveform of the first unit and a second signal waveform of the second unit, based on the first state transition model corresponding to the first unit and a second state transition model of the second unit stored in the storage apparatus.

3. The waveform disaggregation apparatus according to claim 1, wherein the first unit operating under a constraint corresponding to the segment of the first state transition model, when in a first state at a certain time, transitions at a subsequent time to a second state with transition probability of 1.

4. The waveform disaggregation apparatus according to claim 2, wherein the first units the and second units comprise any out of:
first and second units within one facility, the facility configuring one production line;
first and second facilities, each configuring one production line;
a first unit of a first facility configuring a first production line, and a second unit of a second facility configuring a second production line; and
first and second home electrical appliances.

5. The waveform disaggregation apparatus according to claim 1, wherein the processor is further configured to
obtain a composite current waveform of the plurality of units, as the composite signal waveform.

6. The waveform disaggregation apparatus according to claim 1, wherein the processor is further configured to
create a model of an operation state of the unit to store the model in the storage apparatus.

7. The waveform disaggregation apparatus according to claim 1, wherein the processor is further configured to estimate a state of the first unit at a preceding time or at a succeeding time, based on the first state transition model and a prescribed state.

8. The waveform disaggregation apparatus according to claim 1, wherein the processor is further configured to estimate a prescribed state of the first unit, based on the first state transition model and a state at a preceding time or at a succeeding time.

9. The waveform disaggregation apparatus according to claim 1, wherein a model of an operation state of the unit corresponds to a factor of a Factorial Hidden Markov Model (FHMM).

10. The waveform disaggregation apparatus according to claim 1, wherein the processor is further configured to
detect an anomaly of the first unit, from the first signal waveform disaggregated by the estimation section or a prescribed state.

11. The waveform disaggregation apparatus according to claim 10, wherein the processor is further configured to calculate anomaly level indicating an occurrence degree of anomaly, based on the first signal waveform disaggregated by the estimation section or a prescribed state and compares the anomaly level with a threshold to decide whether or not an anomaly occurs.

12. The waveform disaggregation apparatus according to claim 10, wherein the processor is further configured to estimate either one or both of a factor in which an anomaly occurs or a state in which an anomaly occurs, based on the first signal waveform disaggregated by the estimation section or a prescribed state and compares the anomaly level with a threshold to decide whether or not anomaly occurs.

13. The waveform disaggregation apparatus according to claim 12, wherein the processor is further configured to determine priority for each set of the factor and the state, in accordance with an estimated value of the state corresponding to a time at which the anomaly is detected, and
estimate a set of the factor and the state, according to the priority assigned thereto, as either one or both of a factor in which the anomaly occurs and a state in which an anomaly occurs.

14. The waveform disaggregation apparatus according to claim 13, wherein the processor is further configured to adopt as criterion for determining the priority, at least one of the followings:
(a) the state is included in the segment,
(b) a norm of a weight vector of the factorial hidden Markov model corresponding to the state has a large value,
(c) the state is a state where a specific time has elapsed from the start of the segment, and
(d) the state has a large occurrence probability value.

15. A computer-based waveform disaggregation method comprising:
receiving a composite signal waveform of respective signals of a plurality of units including a first unit that operates based on a first state transition model, the first state transition model including a segment in which each state transition in occurs along a one directional single path; and
performing, based on the first state transition model, estimation of a first signal waveform of the first unit from the composite signal waveform to separate the signal waveform therefrom.

16. The waveform disaggregation method according to claim 15, wherein the plurality of units include a second unit, identical to or a type thereof being identical to, the first unit, wherein the method comprises
disaggregating a composite signal waveform of signals of the first and second units into the first signal waveform of the first unit and a second signal waveform of the second unit, based on the first state transition model corresponding to the first unit and a second state transition model of the second unit.

17. The waveform disaggregation method according to claim 15, wherein the first unit operating under a constraint corresponding to the segment of the first state transition model, when in a first state at a certain time, transitions, at a subsequent time, to a second state with transition probability of 1.

18. The waveform disaggregation method according to claim 15, comprising
detecting an anomaly of the unit from the disaggregated signal waveform or a prescribed state.

19. A non-transitory computer readable recording medium storing therein a program causing a computer to execute processing comprising:
receiving a composite signal waveform of signals of a plurality of units including a first unit that operates based on a first state transition model, the first state transition model including a segment in which each state transition in occurs along a one directional single path, and
performing, based on the first state transition model, estimation of a signal waveform of the first unit from the composite signal waveform to separate the signal waveform therefrom.

20. The non-transitory computer readable recording medium according to claim 19, storing the program causing the computer to execute anomaly decision processing to detect an anomaly of the unit from the disaggregated signal waveform or a prescribed state.
